(19) United States
(12) Patent Application Publication
(10) Pub. No.: US 2026/0198192 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-Si (KR)

(72) Inventors: KI NYENG KANG, Yongin-si (KR); SUNGEUN LEE, Yongin-si (KR); Chanju Park, Yongin-si (KR); KEUNKYU SONG, Yongin-si (KR); HOONGI LEE, Yongin-si (KR)

(21) Appl. No.: 19/365,026

(22) Filed: Oct. 21, 2025

(30) Foreign Application Priority Data
Jan. 6, 2025 (KR) 10-2025-0001778

(51) Int. Cl. H10K 59/131

(52) U.S. Cl. CPC H10K 59/131

(57) ABSTRACT

A display device includes substrate including a first-first display area, a second-first display area, and a first-second display area arranged in a first direction, pixel circuits in the first-first display area and the first-second display area, a first driving circuit in the second-first display area and providing a first driving signal to the pixel circuits, light emitting elements in each of the first-first display area, the first-second display area, and the second-first display area, a first data output pad connected to a first pixel circuit in the first-first display area, a second data output pad connected to a second pixel circuit in the first-second display area and spaced apart from the first data output pad in the first direction, and a first control output pad connected to the first driving circuit and located between the first data output pad and the second data output pad in the first direction.

This application claims priority to Korean Patent Application No. 10-2025-0001778, filed on January 6, 2025, and all the benefits accruing therefrom under 35 U.S.C. §119, which is hereby incorporated by reference for all purposes as if fully set forth herein.

### BACKGROUND

### Field

Embodiments relate to a display device and an electronic device including the same. More particularly, embodiments relate to a display device with reduced dead space and an electronic device including the same.

### Description of the Background

Flat panel display devices are replacing cathode ray tube display devices as display devices due to their lightweight and thin characteristics. As representative examples of such flat panel display devices, there are liquid crystal display devices and organic light emitting diode display devices.

The display device includes light emitting elements and driving circuits for driving the light emitting elements. The light emitting elements emit light according to signals and/or voltages applied from the driving circuits, thereby generating an image. In order to improve a reliability and a display quality of the display device, studies on connections between the light emitting elements and circuits are being conducted.

### SUMMARY

Embodiments provide a display device with reduced dead space and improved display quality.

Embodiments also provide an electronic device including the display device.

Additional features of the inventive concepts will be set forth in the description which follows, and in part will be apparent from the description, or may be learned by practice of the inventive concepts.

A display device according to an embodiment includes a substrate, pixel circuits, a first driving circuit, light emitting elements, a first data output pad, a second data output pad, and a first control output pad. The substrate includes a display area and a peripheral area. The display area includes a first-first display area, a first-second display area spaced apart from the first-first display area in a first direction, and a second-first display area located between the first-first display area and the first-second display area in the first direction. The pixel circuits are disposed in the first-first display area and the first-second display area. The first driving circuit is disposed in the second-first display area and provides a first driving signal to the pixel circuits. The light emitting elements are disposed in each of the first-first display area, the first-second display area, and the second-first display area. The first data output pad is disposed in the peripheral area and is electrically connected to a first pixel circuit disposed in the first-first display area among the pixel circuits. The second data output pad is disposed in the peripheral area, is electrically connected to a second pixel circuit disposed in the first-second display area among the pixel circuits, and is spaced apart from the first data output pad in the first direction. The first control output pad is disposed in the peripheral area, is electrically connected to the first driving circuit, and is located between the first data output pad and the second data output pad in the first direction.

In an embodiment, the first data output pad, the second data output pad, and the first control output pad may be disposed in a row in the first direction.

In an embodiment, the display device may further include a first data line, a second data line, a first data connection line, a second data connection line, and a first control connection line. The first data line may be disposed in the first-first display area, and may be electrically connected to the first data output pad. The second data line may be disposed in the first-second display area, and may be electrically connected to the second data output pad. The first data connection line may connect the first data output pad and the first data line. The second data connection line may connect the second data output pad and the second data line, and may be spaced apart from the first data connection line in the first direction. The first control connection line may connect the first control output pad and the first driving circuit, and may be located between the first data connection line and the second data connection line in the first direction.

In an embodiment, the display device may further include a first crack detection circuit disposed between the first data output pad and the first-first display area in a second direction crossing the first direction, and a second crack detection circuit disposed between the second data output pad and the first-second display area in the second direction. The second crack detection circuit may be spaced apart from the first crack detection circuit in the first direction. The first control connection line may be located between the first crack detection circuit and the second crack detection circuit in the first direction.

In an embodiment, the display area may further include a first-third display area spaced apart from the first-second display area in the first direction and a second-second display area located between the first-second display area and the first-third display area in the first direction. The pixel circuits may be further disposed in the first-third display area. The light emitting elements may be further disposed in the first-third display area and the second-second display area.

In an embodiment, the display device may further include a second driving circuit, a third data output pad, and a second control output pad. The second driving circuit may be disposed in the second-second display area, and may provide a second driving signal to the pixel circuits. The third data output pad may be disposed in the peripheral area, may be electrically connected to a third pixel circuit disposed in the first-third display area among the pixel circuits, and may be spaced apart from the second data output pad in the first direction. The second control output pad may be disposed in the peripheral area, may be electrically connected to the second driving circuit, and may be located between the second data output pad and the third data output pad in the first direction.

In an embodiment, each of the first driving circuit and the second driving circuit may be a scan driving circuit or an emission driving circuit.

In an embodiment, the pixel circuits may further include a third pixel circuit disposed in the first-first display area. The light emitting elements may include a first light emitting element disposed in the second-first display area and electrically connected to the first pixel circuit, and a second light emitting element disposed in the first-first display area and electrically connected to the third pixel circuit.

In an embodiment, the first pixel circuit may be located between the second-first display area and the third pixel circuit in the first direction.

In an embodiment, the display device may further include a bridge line and a first shield layer disposed between the bridge line and the first driving circuit. The bridge line may include a first end portion electrically connected to the first pixel circuit in the first-first display area and a second end portion electrically connected to the first light emitting element in the second-first display area.

In an embodiment, the first shield layer may define a first through hole and a first dummy hole. A conductive pattern, which is in a same layer as the first shield layer, may be disposed inside the first through hole. There is no conductive pattern inside the first dummy hole.

In an embodiment, the display device may further include a driving signal line disposed on the first shield layer. The driving signal line may transmit the first driving signal provided from the first driving circuit to the first pixel circuit and the third pixel circuit.

In an embodiment, the driving signal line may be in a same layer as the bridge line.

In an embodiment, the display device may further include a second shield layer disposed on the bridge line.

In an embodiment, the display device may further include a common voltage line disposed in the display area and to which a common voltage is applied. The common voltage line may be connected to a common electrode of the light emitting elements in the display area.

In an embodiment, the display device may further include an organic encapsulating layer disposed on the light emitting elements, an input sensing layer disposed on the organic encapsulating layer and including a first sensing electrode and a second sensing electrode, and a first trace line disposed under the light emitting elements and electrically connecting the first sensing electrode and a first sensing pad.

In an embodiment, the first trace line may include a first end portion connected to the first sensing pad in the peripheral area, a second end portion connected to the first sensing electrode in the peripheral area, and a connection portion connecting the first end portion and the second end portion and extending through the display area.

In an embodiment, the second end portion of the first trace line may be connected to the first sensing electrode outside the organic encapsulating layer in a plan view.

In an embodiment, the display device may further include a second trace line in a same layer as the first trace line and electrically connecting the second sensing electrode and a second sensing pad.

An electronic device according to an embodiment includes a display device displaying an image and a housing accommodating the display device. The display device includes a substrate, pixel circuits, a first driving circuit, light emitting elements, a first data output pad, a second data output pad, and a first control output pad. The substrate includes a display area and a peripheral area. The display area includes a first-first display area, a first-second display area spaced apart from the first-first display area in a first direction, and a second-first display area located between the first-first display area and the first-second display area in the first direction. The pixel circuits are disposed in the first-first display area and the first-second display area. The first driving circuit is disposed in the second-first display area and provides a first driving signal to the pixel circuits. The light emitting elements are disposed in each of the first-first display area, the first-second display area, and the second-first display area. The first data output pad is disposed in the peripheral area and is electrically connected to a first pixel circuit disposed in the first-first display area among the pixel circuits. The second data output pad is disposed in the peripheral area, is electrically connected to a second pixel circuit disposed in the first-second display area among the pixel circuits, and is spaced apart from the first data output pad in the first direction. The first control output pad is disposed in the peripheral area, is electrically connected to the first driving circuit, and is located between the first data output pad and the second data output pad in the first direction.

According to embodiments, the dead space of the display device may be reduced, and the display quality of the display device may be improved.

It is to be understood that both the foregoing general description and the following detailed description are for example and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure, and together with the description serve to explain the present disclosure.

FIG. 1 is a block diagram illustrating a display device according to an embodiment.

FIG. 2 is an equivalent circuit diagram illustrating a pixel according to an embodiment.

FIG. 3 is a plan view illustrating a display device according to an embodiment.

FIG. 4 is an enlarged plan view illustrating an area A of FIG. 3 according to an embodiment.

FIG. 5 is an enlarged plan view illustrating an area A of FIG. 3 according to an embodiment.

FIG. 6 is a cross-sectional view illustrating an example of a display panel included in the display device of FIG. 3.

FIG. 7 is a plan view illustrating an example of common voltage lines included in the display device of FIG. 3.

FIG. 8 is a plan view illustrating another example of common voltage lines included in the display device of FIG. 3.

FIG. 9 is a cross-sectional view illustrating an example of a connection portion of a common voltage line included in the display device of FIG. 3.

FIG. 10 is a cross-sectional view illustrating another example of a connection portion of a common voltage line included in the display device of FIG. 3.

FIG. 11 is a plan view illustrating an example of trace lines included in a display panel according to an embodiment.

FIG. 12 is a cross-sectional view illustrating an example of the display panel of FIG. 11.

FIG. 13 is a block diagram illustrating an electronic device according to an embodiment.

FIG. 14 is a view illustrating an example in which the electronic device of FIG. 13 is implemented as a smartphone.

FIG. 15 is an exploded perspective view of the electronic device of FIG. 14.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

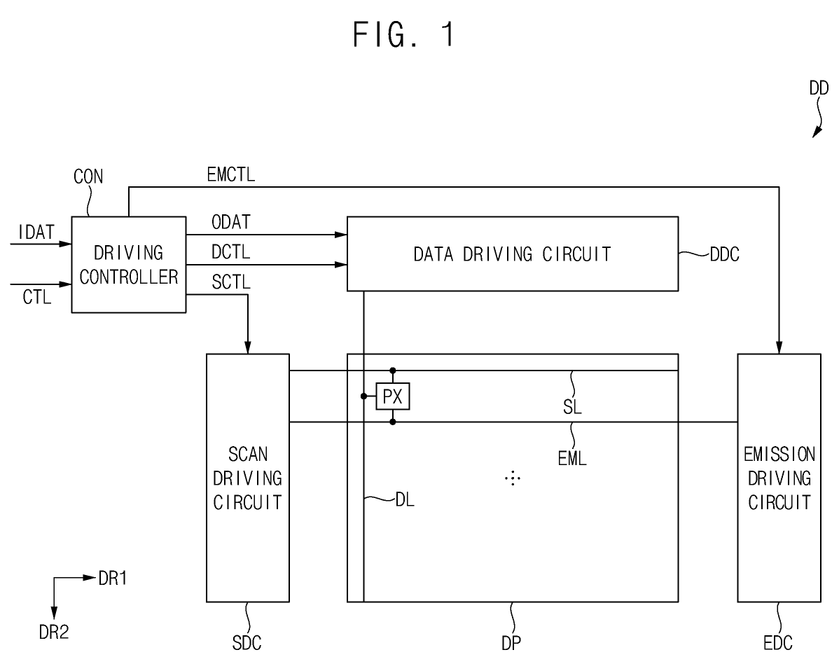

FIG. 1 is a block diagram illustrating a display device according to an embodiment.

Referring to FIG. 1, a display device DD according to an embodiment may include a display panel DP including pixels PX and a panel driver for driving the display panel DP based on input image data IDAT. In an embodiment, the panel driver may include a data driving circuit DDC, a scan driving circuit SDC, an emission driving circuit EDC, and a driving controller CON. The data driving circuit DDC may provide data signals to the pixels PX. The scan driving circuit SDC may provide scan signals to the pixels PX. The emission driving circuit EDC may provide emission signals to the pixels PX. The driving controller CON may control the data driving circuit DDC, the scan driving circuit SDC, and the emission driving circuit EDC.

The display panel DP may include a display area on which an image is displayed and a peripheral area located around the display area. The display panel DP may include scan lines SL, data lines DL, emission lines EML, and the pixels PX. The pixels PX may be electrically connected to the scan lines SL, the data lines DL, and the emission lines EML. For example, the scan lines SL may each extend in a first direction DR1. The data lines DL may each extend in a second direction DR2 crossing the first direction DR1. The emission lines EML may each extend in the first direction DR1.

The data driving circuit DDC may generate the data signals based on output image data ODAT and a data control signal DCTL received from the driving controller CON, and may provide the data signals to the pixels PX through the data lines DL. In an embodiment, the data control signal DCTL may include an output data enable signal, a horizontal start signal, and a load signal, but embodiments are not limited thereto. In an embodiment, the data driving circuit DDC and the driving controller CON may be implemented as a single integrated circuit, and the integrated circuit may be referred to as a timing controller embedded data driver (TED). In an embodiment, the data driving circuit DDC and the driving controller CON may be implemented as separate integrated circuits.

The scan driving circuit SDC may generate the scan signals based on a scan control signal SCTL received from the driving controller CON, and may sequentially provide the scan signals to the pixels PX, on a row-by-row basis, through the scan lines SL. In an embodiment, the scan control signal SCTL may include a scan start signal, a scan clock signal, or the like, but embodiments are not limited thereto. In an embodiment, the scan driving circuit SDC may be integrated or formed in the display panel DP.

The emission driving circuit EDC may generate the emission signals based on an emission control signal EMCTL received from the driving controller CON, and may sequentially provide the emission signals to the pixels PX, on a row-by-row basis, through the emission lines EML. In an embodiment, the emission control signal EMCTL may include an emission start signal, an emission clock signal, or the like, but embodiments are not limited thereto. In an embodiment, the emission driving circuit EDC may be integrated or formed in the display panel DP.

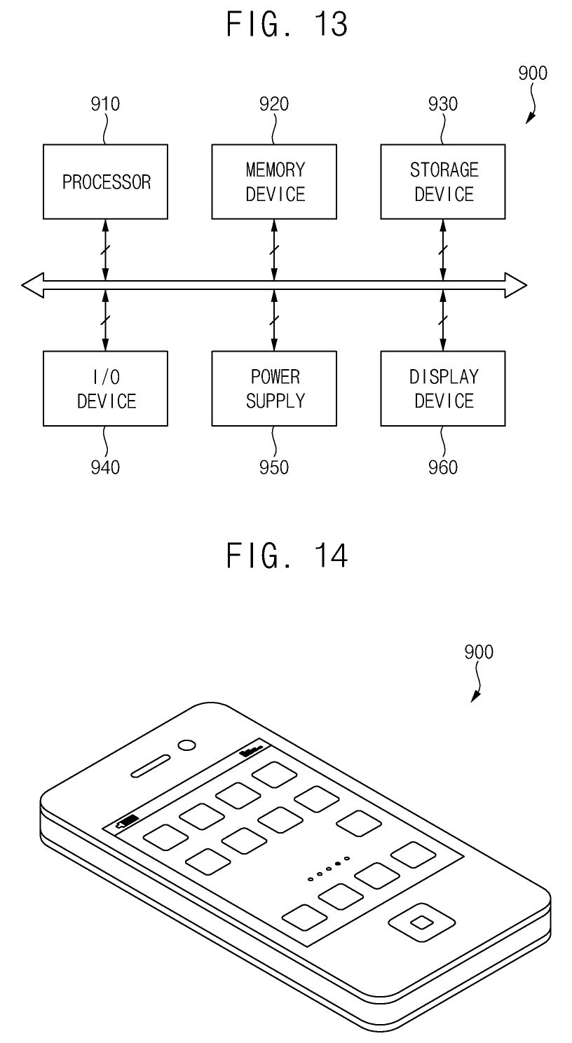

The driving controller CON may receive the input image data IDAT and an input control signal CTL from an external host processor (e.g., a processor 910 of FIG. 13). In an embodiment, the input control signal CTL may include a vertical synchronization signal, a horizontal synchronization signal, an input data enable signal, a master clock signal, or the like, but embodiments are not limited thereto. The driving controller CON may generate the output image data ODAT, the data control signal DCTL, the scan control signal SCTL, and the emission control signal EMCTL based on the input image data IDAT and the input control signal CTL. In addition, the driving controller CON may control the data driving circuit DDC by providing the output image data ODAT and the data control signal DCTL to the data driving circuit DDC, control the scan driving circuit SDC by providing the scan control signal SCTL to the scan driving circuit SDC, and control the emission driving circuit EDC by providing the emission control signal EMCTL to the emission driving circuit EDC.

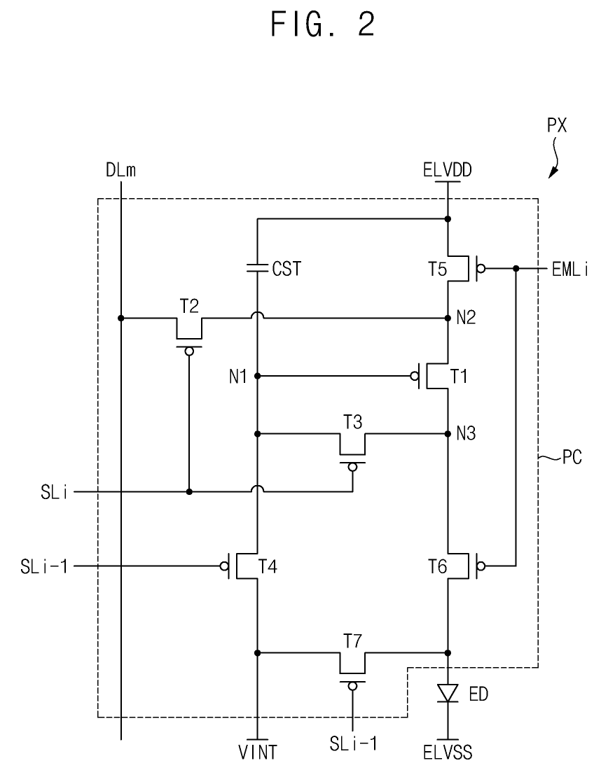

FIG. 2 is an equivalent circuit diagram illustrating a pixel according to an embodiment.

Each of the pixels PX may include a pixel circuit PC and a light emitting element ED. The pixel circuits PC may have substantially the same structure. Hereinafter, a pixel PX connected to a m-th data line DLm and a i-th scan line SLi will be described (m and I are natural numbers greater than 0).

Referring to FIG. 2, the pixel circuit PC may include first to seventh pixel transistors T1, T2, T3, T4, T5, T6, and T7, and a storage capacitor CST.

The first pixel transistor T1 may include a gate electrode connected to a first node N1, a first electrode connected to a second node N2, and a second electrode connected to a third node N3.

The second pixel transistor T2 may include a gate electrode connected to the i-th scan line SLi, a first electrode connected to the m-th data line DLm, and a second electrode connected to the second node N2.

The third pixel transistor T3 may include a gate electrode connected to the i-th scan line SLi, a first electrode connected to the first node N1, and a second electrode connected to the third node N3.

The fourth pixel transistor T4 may include a gate electrode connected to a i−1th scan line SLi−1, a first electrode to which an initialization signal VINT is applied, and a second electrode connected to the first node N1.

The fifth pixel transistor T5 may include a gate electrode connected to a i-th emission line EMLi, a first electrode to which a driving voltage ELVDD is applied, and a second electrode connected to the second node N2. The driving voltage ELVDD may be a high power supply voltage.

The sixth pixel transistor T6 may include a gate electrode connected to the i-th emission line EMLi, a first electrode connected to the third node N3, and a second electrode connected to a first electrode (e.g., an anode) of the light emitting element ED.

The seventh pixel transistor T7 may include a gate electrode connected to the i−1th scan line SLi−1, a first electrode to which the initialization signal VINT is applied, and a second electrode connected to the first electrode of the light emitting element ED.

The storage capacitor CST may include a first electrode to which the driving voltage ELVDD is applied and a second electrode connected to the first node N1.

The light emitting element ED may include the first electrode and a second electrode (e.g., a cathode) to which a common voltage ELVSS is applied. The common voltage ELVSS may be a low power supply voltage. The light emitting element ED may emit light based on a driving current provided from the pixel circuit PC. For example, the light emitting element ED may include an organic light emitting diode, an inorganic light emitting diode, a quantum dot light emitting diode, a micro light emitting diode, or the like.

In FIG. 2, the first to seventh pixel transistors T1, T2, T3, T4, T5, T6, and T7 are illustrated as p-channel metal oxide semiconductor (PMOS) transistors, but embodiments are not limited thereto. For example, the third pixel transistor T3 and the fourth pixel transistor T4 may be n-channel metal oxide semiconductor (NMOS) transistors, and the other pixel transistors may be PMOS transistors. For another example, all of the first to seventh pixel transistors T1, T2, T3, T4, T5, T6, and T7 may be NMOS transistors.

In addition, the number of pixel transistors and the number of capacitors illustrated in FIG. 2 is only an example and may be variously changed according to embodiments.

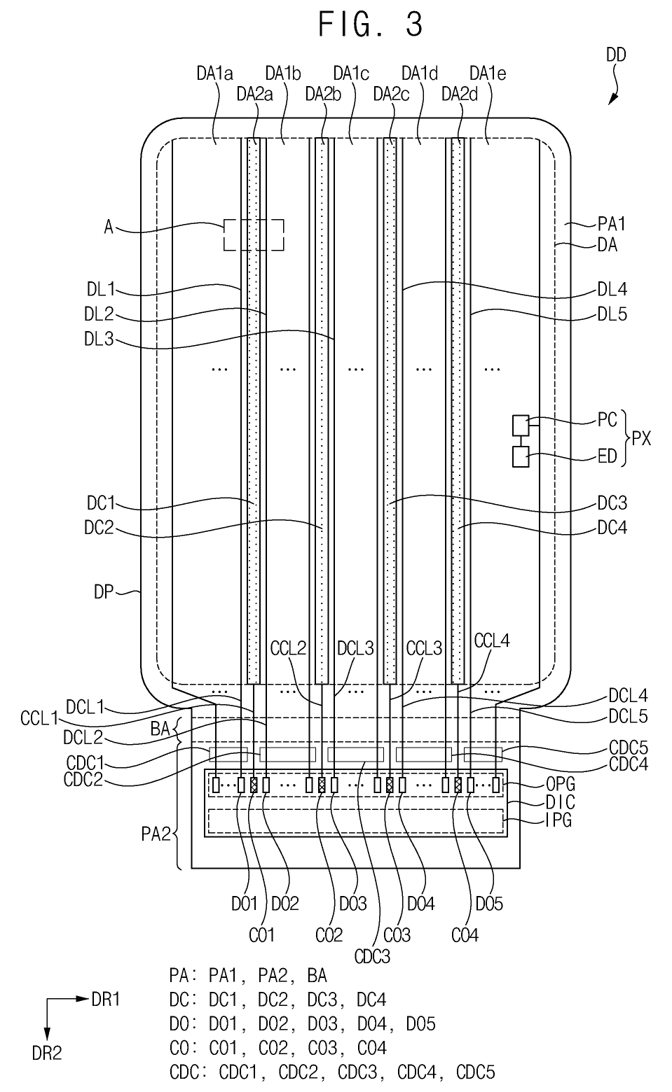

FIG. 3 is a plan view illustrating a display device according to an embodiment.

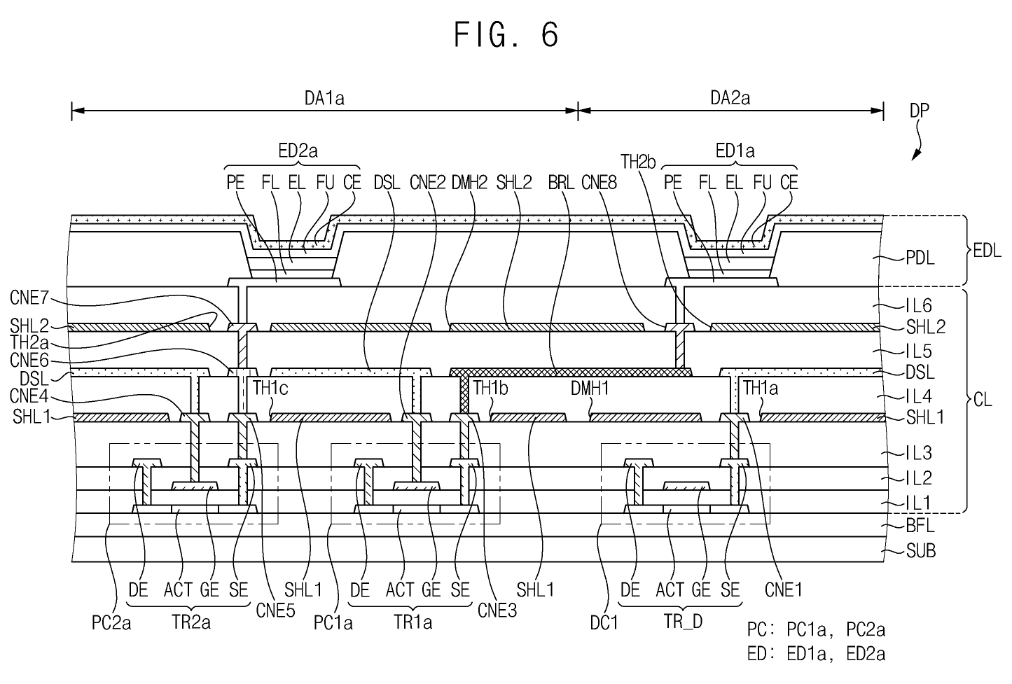

Referring to FIG. 3, the display device DD may include the display panel DP and a driving chip DIC. In an embodiment, the display panel DP (or a substrate SUB of FIG. 6) may include the display area DA and the peripheral area PA. The display area DA may display an image. For example, in a plan view, the display area DA may have a rectangular shape, and corners of the display area DA may each have rounded curved shapes, but embodiments are not limited thereto.

The peripheral area PA may be located around the display area DA. In an embodiment, the peripheral area PA may include a first peripheral area PA1, a second peripheral area PA2, and a bending area BA. The first peripheral area PA1 may surround an outer edge of the display area DA in a plan view. The second peripheral area PA2 may be located in the second direction DR2 from the display area DA and the first peripheral area PA1 in a plan view. The bending area BA may be located between the first peripheral area PA1 and the second peripheral area PA2 in a plan view. The bending area BA may be a portion where the display device DD is bent. The second peripheral area PA2 may be spaced apart from the first peripheral area PA1 in the second direction DR2 with the bending area BA interposed therebetween in a plan view.

In an embodiment, the driving chip DIC may be disposed on the display panel DP in the second peripheral area PA2. For example, the driving chip DIC may be connected to the display panel DP through an anisotropic conductive film (ACF). In an embodiment, the driving chip DIC may include the data driving circuit DDC and the driving controller CON of FIG. 1.

In an embodiment, the display panel DP may include the pixels PX, driving circuits DC, an input pad group IPG, an output pad group OPG, and crack detection circuits CDC.

The pixels PX and the driving circuits DC may be disposed in the display area DA. In an embodiment, the driving circuits DC disposed in the display area DA may each extend in the second direction DR2, and may be spaced apart from each other in the first direction DR1. As the driving circuits DC are disposed in the display area DA, an area of the peripheral area PA may be reduced, and a dead space of the display device DD may be reduced.

Hereinafter, embodiments will be described focusing on an example in which four driving circuits DC are disposed to be spaced apart from each other in the first direction DR1 in the display area DA, as illustrated in FIG. 3. However, this is an example, and embodiments are not limited thereto, and the number of driving circuits DC in the display area DA may be variously changed to three or less or five or more.

The display area DA may include first display areas and second display areas which are disposed in the first direction DR1. The first display areas may be areas where the driving circuits DC are not disposed, and the second display areas may be areas where the driving circuits DC are disposed. Each of the second display areas may be located between two adjacent first display areas which are adjacent to each other in the first direction DR1. The pixel circuits PC may be disposed in the first display areas, and may not be disposed in the second display areas. The light emitting elements ED may be disposed in both the first display areas and the second display areas. This will be described in detail later.

In an embodiment, the first display areas may include a first-first display area DA1a, a first-second display area DA1b, a first-third display area DA1c, a first-fourth display area DA1d, and a first-fifth display area DA1e which are spaced apart from each other in the first direction DR1. The second display areas may include a second-first display area DA2a, a second-second display area DA2b, a second-third display area DA2c, and a second-fourth display area DA2d which are spaced apart from each other in the first direction DR1. In a plan view, the first-second display area DA1b may be spaced apart from the first-first display area DA1a in the first direction DR1, and the second-first display area DA2a may be located between the first-first display area DA1a and the first-second display area DA1b in the first direction DR1. In a plan view, the first-third display area DA1c may be spaced apart from the first-second display area DA1b in the first direction DR1, and the second-second display area DA2b may be located between the first-second display area DA1b and the first-third display area DA1c in the first direction DR1. In a plan view, the first-fourth display area DA1d may be spaced apart from the first-third display area DA1c in the first direction DR1, and the second-third display area DA2c may be located between the first-third display area DA1c and the first-fourth display area DA1d in the first direction DR1. In a plan view, the first-fifth display area DA1e may be spaced apart from the first-fourth display area DA1d in the first direction DR1, and the second-fourth display area DA2d may be located between the first-fourth display area DA1d and the first-fifth display area DA1e in the first direction DR1.

The pixel circuits PC may be disposed in the first-first display area DA1a, the first-second display area DA1b, the first-third display area DA1c, the first-fourth display area DA1d, and the first-fifth display area DA1e. The pixel circuits PC may not be disposed in the second-first display area DA2a, the second-second display area DA2b, the second-third display area DA2c, and the second-fourth display area DA2d.

A first driving circuit DC1 may be disposed in the second-first display area DA2a, and may provide a first driving signal to the pixel circuits PC. A second driving circuit DC2 may be disposed in the second-second display area DA2b, and may provide a second driving signal to the pixel circuits PC. A third driving circuit DC3 may be disposed in the second-third display area DA2c, and may provide a third driving signal to the pixel circuits PC. A fourth driving circuit DC4 may be disposed in the second-fourth display area DA2d, and may provide a fourth driving signal to the pixel circuits PC. For example, each of the first to fourth driving signals may be the scan signal or the emission signal.

Each of the first to fourth driving circuits DC1, DC2, DC3, and DC4 may not overlap the pixel circuits PC in a plan view. Each of the first to fourth driving circuits DC1, DC2, DC3, and DC4 may be disposed between the pixel circuits PC in the first direction DR1 in a plan view.

Each of the first to fourth driving circuits DC1, DC2, DC3, and DC4 may be the scan driving circuit SDC or the emission driving circuit EDC of FIG. 1, but embodiments are not limited thereto. For example, when the first driving circuit DC1 is the scan driving circuit SDC of FIG. 1, the first driving signal may be the scan signal, and when the first driving circuit DC1 is the emission driving circuit EDC of FIG. 1, the first driving signal may be the emission signal. In an embodiment, at least some of the first to fourth driving circuits DC1, DC2, DC3, and DC4 may be same circuit. In an embodiment, the first to fourth driving circuits DC1, DC2, DC3, and DC4 may be different circuits.

The input pad group IPG, the output pad group OPG, and the crack detection circuits CDC may be disposed in the peripheral area PA. In an embodiment, the input pad group IPG, the output pad group OPG, and the crack detection circuits CDC may be disposed in the second peripheral area PA2. The input pad group IPG and the output pad group OPG may overlap the driving chip DIC in a plan view.

The input pad group IPG may include input pads. The input pads may transmit signals input from a circuit board, which is connected to an end of the display panel DP, to the driving chip DIC.

The output pad group OPG may include control output pads CO and data output pads DO. The control output pads CO may receive control signals from the driving chip DIC. For example, each of the control output pads CO may receive the scan control signal SCTL or the emission control signal EMCTL from the driving controller CON included in the driving chip DIC (see FIG. 1). Each of the control output pads CO may transmit the control signal to corresponding one of the driving circuits DC through a control connection line.

Each of the data output pads DO may receive the data signals from the driving chip DIC. For example, each of the data output pads DO may receive the data signals from the data driving circuit DDC included in the driving chip DIC (see FIG. 1). Each of the data output pads DO may transmit the data signals to corresponding one of the data lines through a data connection line.

In an embodiment, the control output pads CO may be disposed to correspond to the driving circuits DC. In a plan view, the control output pads CO may be disposed to correspond to the second-first display area DA2a, the second-second display area DA2b, the second-third display area DA2c, and the second-fourth display area DA2d in the second direction DR2, and the data output pads DO may be disposed to correspond to the first-first display area DA1a, the first-second display area DA1b, the first-third display area DA1c, the first-fourth display area DA1d, and the first-fifth display area DA1e in the second direction DR2.

A first data output pad DO1 may be disposed to correspond to the first-first display area DA1a. In an embodiment, in a plan view, the first data output pad DO1 may overlap the first-first display area DA1a in the second direction DR2.

The first data output pad DO1 may be electrically connected to a first data line DL1 disposed in the first-first display area DA1a through a first data connection line DCL1. The first data line DL1 may be electrically connected to some of the pixel circuits PC disposed in the first-first display area DA1a. That is, the first data output pad DO1 may be electrically connected to some of the pixel circuits PC disposed in the first-first display area DA1a through the first data connection line DCL1 and the first data line DL1.

A second data output pad DO2 may be disposed to correspond to the first-second display area DA1b. In an embodiment, in a plan view, the second data output pad DO2 may overlap the first-second display area DA1b in the second direction DR2. In a plan view, the second data output pad DO2 may be spaced apart from the first data output pad DO1 in the first direction DR1.

The second data output pad DO2 may be electrically connected to a second data line DL2 disposed in the first-second display area DA1b through a second data connection line DCL2. The second data line DL2 may be electrically connected to some of the pixel circuits PC disposed in the first-second display area DA1b. That is, the second data output pad DO2 may be electrically connected to some of the pixel circuits PC disposed in the first-second display area DA1b through the second data connection line DCL2 and the second data line DL2. In a plan view, the second data line DL2 may be spaced apart from the first data line DL1 in the first direction DR1, and the second data connection line DCL2 may be spaced apart from the first data connection line DCL1 in the first direction DR1.

A first control output pad CO1 may be disposed to correspond to the second-first display area DA2a. In an embodiment, in a plan view, the first control output pad CO1 may overlap the second-first display area DA2a in the second direction DR2. In a plan view, the first control output pad CO1 may be located between the first data output pad DO1 and the second data output pad DO2 in the first direction DR1.

The first control output pad CO1 may be electrically connected to the first driving circuit DC1 disposed in the second-first display area DA2a through a first control connection line CCL1. In a plan view, the first control connection line CCL1 may be located between the first data connection line DCL1 and the second data connection line DCL2 in the first direction DR1.

A third data output pad DO3 may be disposed to correspond to the first-third display area DA1c. In an embodiment, in a plan view, the third data output pad DO3 may overlap the first-third display area DA1c in the second direction DR2. In a plan view, the third data output pad DO3 may be spaced apart from the second data output pad DO2 in the first direction DR1.

The third data output pad DO3 may be electrically connected to a third data line DL3 disposed in the first-third display area DA1c through a third data connection line DCL3. The third data line DL3 may be electrically connected to some of the pixel circuits PC disposed in the first-third display area DA1c. That is, the third data output pad DO3 may be electrically connected to some of the pixel circuits PC disposed in the first-third display area DA1c through the third data connection line DCL3 and the third data line DL3. In a plan view, the third data line DL3 may be spaced apart from the second data line DL2 in the first direction DR1, and the third data connection line DCL3 may be spaced apart from the second data connection line DCL2 in the first direction DR1.

A second control output pad CO2 may be disposed to correspond to the second-second display area DA2b. In an embodiment, in a plan view, the second control output pad CO2 may overlap the second-second display area DA2b in the second direction DR2. In a plan view, the second control output pad CO2 may be located between the second data output pad DO2 and the third data output pad DO3 in the first direction DR1.

The second control output pad CO2 may be electrically connected to the second driving circuit DC2 disposed in the second-second display area DA2b through a second control connection line CCL2. In a plan view, the second control connection line CCL2 may be located between the second data connection line DCL2 and the third data connection line DCL3 in the first direction DR1.

A fourth data output pad DO4 may be disposed to correspond to the first-fourth display area DA1d. In an embodiment, in a plan view, the fourth data output pad DO4 may overlap the first-fourth display area DA1d in the second direction DR2. In a plan view, the fourth data output pad DO4 may be spaced apart from the third data output pad DO3 in the first direction DR1.

The fourth data output pad DO4 may be electrically connected to a fourth data line DL4 disposed in the first-fourth display area DA1d through a fourth data connection line DCL4. The fourth data line DL4 may be electrically connected to some of the pixel circuits PC disposed in the first-fourth display area DA1d. That is, the fourth data output pad DO4 may be electrically connected to some of the pixel circuits PC disposed in the first-fourth display area DA1d through the fourth data connection line DCL4 and the fourth data line DL4. In a plan view, the fourth data line DL4 may be spaced apart from the third data line DL3 in the first direction DR1, and the fourth data connection line DCL4 may be spaced apart from the third data connection line DCL3 in the first direction DR1.

A third control output pad CO3 may be disposed to correspond to the second-third display area DA2c. In an embodiment, in a plan view, the third control output pad CO3 may overlap the second-third display area DA2c in the second direction DR2. In a plan view, the third control output pad CO3 may be located between the third data output pad DO3 and the fourth data output pad DO4 in the first direction DR1.

The third control output pad CO3 may be electrically connected to the third driving circuit DC3 disposed in the second-third display area DA2c through a third control connection line CCL3. In a plan view, the third control connection line CCL3 may be located between the third data connection line DCL3 and the fourth data connection line DCL4 in the first direction DR1.

A fifth data output pad DO5 may be disposed to correspond to the first-fifth display area DA1e. In an embodiment, in a plan view, the fifth data output pad DO5 may overlap the first-fifth display area DA1e in the second direction DR2. In a plan view, the fifth data output pad DO5 may be spaced apart from the fourth data output pad DO4 in the first direction DR1.

The fifth data output pad DO5 may be electrically connected to a fifth data line DL5 disposed in the first-fifth display area DA1e through a fifth data connection line DCL5. The fifth data line DL5 may be electrically connected to some of the pixel circuits PC disposed in the first-fifth display area DA1e. That is, the fifth data output pad DO5 may be electrically connected to some of the pixel circuits PC disposed in the first-fifth display area DA1e through the fifth data connection line DCL5 and the fifth data line DL5. In a plan view, the fifth data line DL5 may be spaced apart from the fourth data line DL4 in the first direction DR1, and the fifth data connection line DCL5 may be spaced apart from the fourth data connection line DCL4 in the first direction DR1.

A fourth control output pad CO4 may be disposed to correspond to the second-fourth display area DA2d. In an embodiment, in a plan view, the fourth control output pad CO4 may overlap the second-fourth display area DA2d in the second direction DR2. In a plan view, the fourth control output pad CO4 may be located between the fourth data output pad DO4 and the fifth data output pad DO5 in the first direction DR1.

The fourth control output pad CO4 may be electrically connected to the fourth driving circuit DC4 disposed in the second-fourth display area DA2d through a fourth control connection line CCL4. In a plan view, the fourth control connection line CCL4 may be located between the fourth data connection line DCL4 and the fifth data connection line DCL5 in the first direction DR1.

In an embodiment, the first data output pad DO1, the first control output pad CO1, the second data output pad DO2, the second control output pad CO2, the third data output pad DO3, the third control output pad CO3, the fourth data output pad DO4, the fourth control output pad CO4, and the fifth data output pad DO5 may be disposed in a row in the first direction DR1.

The crack detection circuits CDC may be disposed adjacent to the output pad group OPG. In an embodiment, the crack detection circuits CDC may be disposed between the output pad group OPG and the display area DA in a plan view. Each of the crack detection circuits CDC may be connected to a crack detection line to detect whether a crack exists in the display panel DP. In an embodiment, the display panel DP may include first to fifth crack detection circuits CDC1, CDC2, CDC3, CDC4, and CDC5 spaced apart from each other in the first direction DR1.

In an embodiment, in a plan view, the first crack detection circuit CDC1 may be disposed between the first data output pad DO1 and the first-first display area DA1a in the second direction DR2. For example, the first crack detection circuit CDC1 may be electrically connected to the first data connection line DCL1.

In an embodiment, in a plan view, the second crack detection circuit CDC2 may be disposed between the second data output pad DO2 and the first-second display area DA1b in the second direction DR2. For example, the second crack detection circuit CDC2 may be electrically connected to the second data connection line DCL2. In an embodiment, in a plan view, the first control connection line CCL1 may be located between the first crack detection circuit CDC1 and the second crack detection circuit CDC2 in the first direction DR1.

In an embodiment, in a plan view, the third crack detection circuit CDC3 may be disposed between the third data output pad DO3 and the first-third display area DA1c in the second direction DR2. For example, the third crack detection circuit CDC3 may be electrically connected to the third data connection line DCL3. In an embodiment, in a plan view, the second control connection line CCL2 may be located between the second crack detection circuit CDC2 and the third crack detection circuit CDC3 in the first direction DR1.

In an embodiment, in a plan view, the fourth crack detection circuit CDC4 may be disposed between the fourth data output pad DO4 and the first-fourth display area DA1d in the second direction DR2. For example, the fourth crack detection circuit CDC4 may be electrically connected to the fourth data connection line DCL4. In an embodiment, in a plan view, the third control connection line CCL3 may be located between the third crack detection circuit CDC3 and the fourth crack detection circuit CDC4 in the first direction DR1.

In an embodiment, in a plan view, the fifth crack detection circuit CDC5 may be disposed between the fifth data output pad DO5 and the first-fifth display area DA1e in the second direction DR2. For example, the fifth crack detection circuit CDC5 may be electrically connected to the fifth data connection line DCL5. In an embodiment, in a plan view, the fourth control connection line CCL4 may be located between the fourth crack detection circuit CDC4 and the fifth crack detection circuit CDC5 in the first direction DR1.

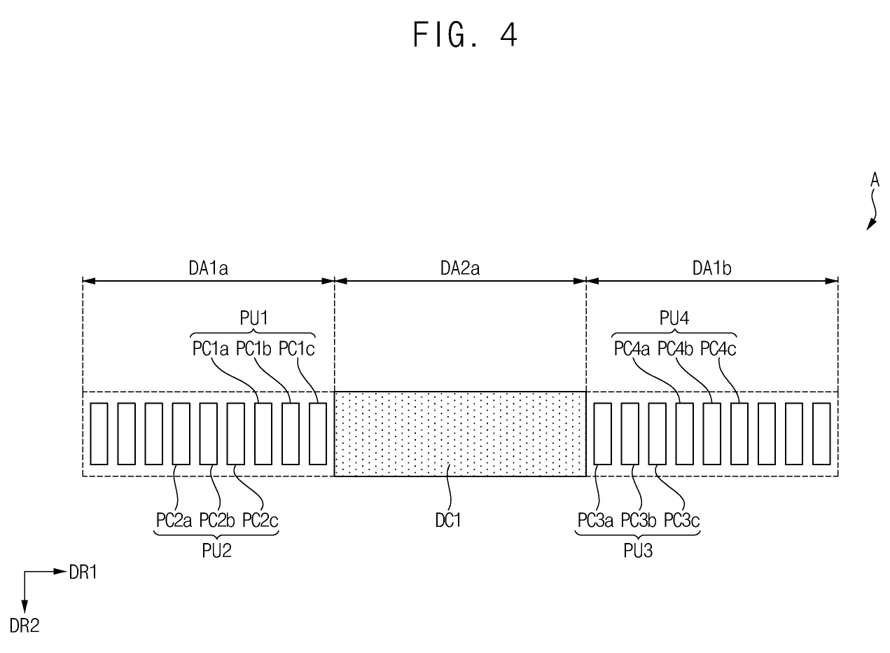

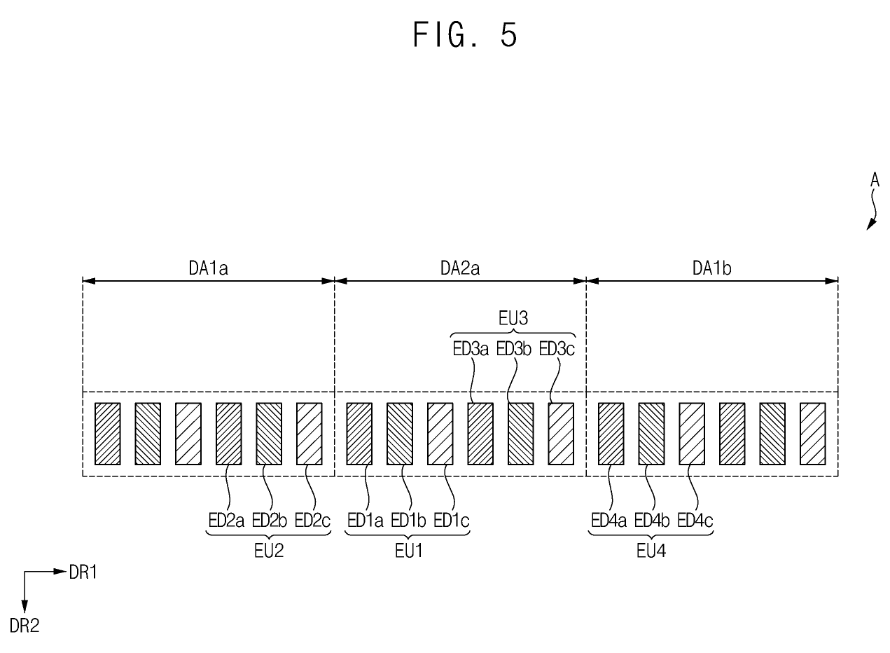

FIGS. 4 and 5 are enlarged plan views illustrating an area A of FIG. 3.

Hereinafter, an arrangement relationship of the pixel circuits PC and the light emitting elements ED in the first display areas and the second display areas will be described with reference to FIGS. 3 to 5. FIG. 4 illustrates the pixel circuits PC and the first driving circuit DC1, and FIG. 5 illustrates the light emitting elements ED respectively electrically connected to the pixel circuits PC of FIG. 4.

Referring to FIGS. 3 to 5, a first unit pixel circuit PU1 and a second unit pixel circuit PU2 may be disposed in the first-first display area DA1a, and a third unit pixel circuit PU3 and a fourth unit pixel circuit PU4 may be disposed in the first-second display area DA1b. The first unit pixel circuit PU1 may include a first red pixel circuit PC1a, a first green pixel circuit PC1b, and a first blue pixel circuit PC1c which are disposed in the first direction DR1. The second unit pixel circuit PU2 may include a second red pixel circuit PC2a, a second green pixel circuit PC2b, and a second blue pixel circuit PC2c which are disposed in the first direction DR1. The third unit pixel circuit PU3 may include a third red pixel circuit PC3a, a third green pixel circuit PC3b, and a third blue pixel circuit PC3c which are disposed in a first direction DR1. The fourth unit pixel circuit PU4 may include a fourth red pixel circuit PC4a, a fourth green pixel circuit PC4b, and a fourth blue pixel circuit PC4c which are disposed in the first direction DR1. The first driving circuit DC1 may be disposed in the second-first display area DA2a, and the pixel circuits PC may not be disposed in the second-first display area DA2a.

Each of the first unit pixel circuit PU1 and the third unit pixel circuit PU3 may be adjacent to the second-first display area DA2a (i.e., the first driving circuit DC1). For example, in a plan view, the first unit pixel circuit PU1 may be located between the second-first display area DA2a (i.e., the first driving circuit DC1) and the second unit pixel circuit PU2 in the first direction DR1. For example, in a plan view, the third unit pixel circuit PU3 may be located between the second-first display area DA2a (i.e., the first driving circuit DC1) and the fourth unit pixel circuit PU4 in the first direction DR1.

The light emitting elements ED may be disposed on the pixel circuits PC and the driving circuits DC. A first unit light emitting element EU1 electrically connected to the first unit pixel circuit PU1 may be disposed in the second-first display area DA2a. The first unit light emitting element EU1 may include a first red light emitting element ED1a electrically connected to the first red pixel circuit PC1a, a first green light emitting element ED1b electrically connected to the first green pixel circuit PC1b, and a first blue light emitting element ED1c electrically connected to the first blue pixel circuit PC1c. Each of the first red light emitting element ED1a, the first green light emitting element ED1b, and the first blue light emitting element ED1c may overlap the first driving circuit DC1 in a plan view.

A second unit light emitting element EU2 electrically connected to the second unit pixel circuit PU2 may be disposed in the first-first display area DA1a. The second unit light emitting element EU2 may include a second red light emitting element ED2a electrically connected to the second red pixel circuit PC2a, a second green light emitting element ED2b electrically connected to the second green pixel circuit PC2b, and a second blue light emitting element ED2c electrically connected to the second blue pixel circuit PC2c.

A third unit light emitting element EU3 electrically connected to the third unit pixel circuit PU3 may be disposed in the second-first display area DA2a. The third unit light emitting element EU3 may include a third red light emitting element ED3a electrically connected to the third red pixel circuit PC3a, a third green light emitting element ED3b electrically connected to the third green pixel circuit PC3b, and a third blue light emitting element ED3c electrically connected to the third blue pixel circuit PC3c. Each of the third red light emitting element ED3a, the third green light emitting element ED3b, and the third blue light emitting element ED3c may overlap the first driving circuit DC1 in a plan view.

A fourth unit light emitting element EU4 electrically connected to the fourth unit pixel circuit PU4 may be disposed in the first-second display area DA1b. The fourth unit light emitting element EU4 may include a fourth red light emitting element ED4a electrically connected to the fourth red pixel circuit PC4a, a fourth green light emitting element ED4b electrically connected to the fourth green pixel circuit PC4b, and a fourth blue light emitting element ED4c electrically connected to the fourth blue pixel circuit PC4c.

FIG. 5 illustrates that two unit light emitting elements EU1 and EU3 are disposed in the first direction DR1 in the second-first display area DA2a, but this is an example and embodiments are not limited thereto, and three or more unit light emitting elements may be disposed in the first direction DR1 in the second-first display area DA2a. In addition, FIG. 5 illustrates that the light emitting elements included in each unit light emitting element are disposed in a stripe type, but this is an example and embodiments are not limited thereto, and the light emitting elements included in each unit light emitting element may be disposed in various types, such as a pentile^{TM} type, a diamond pentile^{TM} type, or the like. In addition, the descriptions described above with reference to FIGS. 4 and 5 may be substantially equally applied to the vicinity of the second-second display area DA2b, the vicinity of the second-third display area DA2c, and the vicinity of the second-fourth display area DA2d of FIG. 3.

FIG. 6 is a cross-sectional view illustrating an example of a display panel included in the display device of FIG. 3.

Referring to FIGS. 3 to 6, in an embodiment, the display panel DP may include a substrate SUB, a buffer layer BFL, a circuit layer CL, and a light emitting element layer EDL. The circuit layer CL may include the driving circuits DC, the pixel circuits PC, insulating layers, connection electrodes, a first shield layer SHL1, a driving signal line DSL, a bridge line BRL, and a second shield layer SHL2. The light emitting element layer EDL may include the light emitting elements ED and a pixel defining layer PDL. FIG. 6 illustrates, for convenience, some of the configurations included in the circuit layer CL and some of the configurations included in the light emitting element layer EDL. For example, FIG. 6 illustrates the first red pixel circuit PC1a and the second red pixel circuit PC2a disposed in the first-first display area DA1a among the pixel circuits PC, and the first driving circuit DC1 disposed in the second-first display area DA2a among the driving circuits DC. In addition, FIG. 6 illustrates the first red light emitting element ED1a disposed in the second-first display area DA2a and the second red light emitting element ED2a disposed in the first-first display area DA1a among the light emitting elements ED.

The substrate SUB may be an insulating substrate including or formed of a transparent material or a non-transparent material.

The buffer layer BFL may be disposed on the substrate SUB. The buffer layer BFL may prevent or reduce impurities such as oxygen or moisture from penetrating into an upper portion of the substrate SUB through the substrate SUB. The buffer layer BFL may include an inorganic material, such as a silicon compound, metal oxide, or the like. For example, the buffer layer BFL may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer BFL may have a single layer structure or a multi-layer structure including a plurality of insulating layers. In an embodiment, the buffer layer BFL may be omitted.

The first red pixel circuit PC1a and the second red pixel circuit PC2a may be disposed in the first-first display area DA1a on the buffer layer BFL. The first red pixel circuit PC1a may include a first red pixel transistor TR1a, and the second red pixel circuit PC2a may include a second red pixel transistor TR2a.

The first driving circuit DC1 may be disposed in the second-first display area DA2a on the buffer layer BFL. The first driving circuit DC1 may include a driving circuit transistor TR_D. In an embodiment, the driving circuit transistor TR_D may provide a driving signal to a gate electrode of each of the first red pixel transistor TR1a and the second red pixel transistor TR2a through the driving signal line DSL. For example, in FIG. 6, each of the first red pixel transistor TR1a and the second red pixel transistor TR2a may be the sixth pixel transistor T6 connected to the anode (e.g., a pixel electrode PE of FIG. 6) of the light emitting element ED of FIG. 2. In this case, the first driving circuit DC1 may be the emission driving circuit EDC of FIG. 1 which provides the emission signal to the gate electrode of each of the first red pixel transistor TR1a and the second red pixel transistor TR2a. However, this is an example and embodiments are not limited thereto, and the first driving circuit DC1 may be the scan driving circuit SDC of FIG. 1.

Each of the first red pixel transistor TR1a, the second red pixel transistor TR2a, and the driving circuit transistor TR_D may include an active layer ACT, a gate electrode GE, a source electrode SE, and a drain electrode DE.

The active layer ACT may be disposed on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a source area, a drain area, and a channel area positioned between the source area and the drain area. The source area and the drain area may have higher conductivity than the channel area.

A first insulating layer IL1 may be disposed on the active layer ACT. The first insulating layer IL1 may cover the active layer ACT on the buffer layer BFL. For example, the first insulating layer IL1 may include an inorganic insulating material.

The gate electrode GE may be disposed on the first insulating layer IL1. The gate electrode GE may overlap the channel area of the active layer ACT. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single layer structure or a multi-layer structure including a plurality of conductive layers.

A second insulating layer IL2 may be disposed on the gate electrode GE. The second insulating layer IL2 may cover the gate electrode GE on the first insulating layer IL1. For example, the second insulating layer IL2 may include an inorganic insulating material.

The source electrode SE and the drain electrode DE may be disposed on the second insulating layer IL2. The source electrode SE and the drain electrode DE may be connected to the source area and the drain area of the active layer ACT, respectively. Each of the source electrode SE and the drain electrode DE may include a conductive material. Each of the source electrode SE and the drain electrode DE may have a single layer structure or a multi-layer structure including a plurality of conductive layers.

A third insulating layer IL3 may be disposed on the source electrode SE and the drain electrode DE. For example, the third insulating layer IL3 may include an inorganic insulating material and/or an organic insulating material.

First to fifth connection electrodes CNE1, CNE2, CNE3, CNE4, and CNE5 and the first shield layer SHL1 may be disposed on the third insulating layer IL3. Each of the first to fifth connection electrodes CNE1, CNE2, CNE3, CNE4, and CNE5 and the first shield layer SHL1 may include a conductive material. Each of the first to fifth connection electrodes CNE1, CNE2, CNE3, CNE4, and CNE5 and the first shield layer SHL1 may have a single layer structure or a multi-layer structure including a plurality of conductive layers.

The first connection electrode CNE1 may be electrically connected to the driving circuit transistor TR_D of the first driving circuit DC1. For example, the first connection electrode CNE1 may be connected to the source electrode SE of the driving circuit transistor TR_D through a contact hole penetrating the third insulating layer IL3.

The second connection electrode CNE2 and the third connection electrode CNE3 may be electrically connected to the first red pixel transistor TR1a of the first red pixel circuit PC1a. For example, the second connection electrode CNE2 may be connected to the gate electrode GE of the first red pixel transistor TR1a through a contact hole penetrating the second and third insulating layers IL2 and IL3. For example, the third connection electrode CNE3 may be connected to the source electrode SE of the first red pixel transistor TR1a through a contact hole penetrating the third insulating layer IL3.

The fourth connection electrode CNE4 and the fifth connection electrode CNE5 may be electrically connected to the second red pixel transistor TR2a of the second red pixel circuit PC2a. For example, the fourth connection electrode CNE4 may be connected to the gate electrode GE of the second red pixel transistor TR2a through a contact hole penetrating the second and third insulating layers IL2 and IL3. For example, the fifth connection electrode CNE5 may be connected to the source electrode SE of the second red pixel transistor TR2a through a contact hole penetrating the third insulating layer IL3.

The first shield layer SHL1 may be disposed on the first driving circuit DC1. The first shield layer SHL1 may be disposed between the first driving circuit DC1 and the bridge line BRL. The first shield layer SHL1 may also be disposed on the pixel circuits PC. A voltage may be applied to the first shield layer SHL1, and the first shield layer SHL1 may prevent or reduce signal noise and/or signal coupling occurring above the first driving circuit DC1 and/or above the pixel circuits PC.

The first shield layer SHL1 may define through holes and dummy holes. Each of the through holes and the dummy holes may penetrate the first shield layer SHL1 in a thickness direction. A conductive pattern, which is formed of the same layer as the first shield layer SHL1, may be disposed inside each of the through holes in the first shield layer SHL1. For example, as illustrated in FIG. 6, the first connection electrode CNE1 may be disposed inside a first through hole TH1a in the first shield layer SHL1, the second connection electrode CNE2 and the third connection electrode CNE3 may be disposed inside a second through hole TH1b in the first shield layer SHL1, and the fourth connection electrode CNE4 and the fifth connection electrode CNE5 may be disposed inside a third through hole TH1c in the first shield layer SHL1, but embodiments are not limited thereto.

Unlike the through holes, a conductive pattern, which is formed of the same layer as the first shield layer SHL1, may not be disposed inside each of the dummy holes in the first shield layer SHL1. For example, as illustrated in FIG. 6, there is no conductive pattern inside a first dummy hole DMH1 in the first shield layer SHL1, and the entire first dummy hole DMH1 may be filled with the fourth insulating layer IL4. Each of the dummy holes may serve as a passage for discharging internal gas generated during forming the insulating layer. That is, each of the dummy holes may be an outgassing passage.

In an embodiment, the first to fifth connection electrodes CNE1, CNE2, CNE3, CNE4, and CNE5 and the first shield layer SHL1 may be disposed in a same layer. For example, the first to fifth connection electrodes CNE1, CNE2, CNE3, CNE4, and CNE5 and the first shield layer SHL1 may include the same material, and may be substantially simultaneously formed.

A fourth insulating layer IL4 may be disposed on the first to fifth connection electrodes CNE1, CNE2, CNE3, CNE4, and CNE5 and the first shield layer SHL1. For example, the fourth insulating layer IL4 may include an organic insulating material.

The driving signal line DSL, the bridge line BRL, and a sixth connection electrode CNE6 may be disposed on the fourth insulating layer IL4. Each of the driving signal line DSL, the bridge line BRL, and the sixth connection electrode CNE6 may include a conductive material. Each of the driving signal line DSL, the bridge line BRL, and the sixth connection electrode CNE6 may have a single layer structure or a multi-layer structure including a plurality of conductive layers.

The driving signal line DSL may transmit the driving signal (e.g., the emission signal or the scan signal) provided from the first driving circuit DC1 to the pixel circuits PC.

FIG. 6 illustrates that the driving signal line DSL includes portions separated from each other, the driving signal line DSL may not be separated and may be integrally connected. For example, the driving signal line DSL may be connected to each of the first connection electrode CNE1, the second connection electrode CNE2, and the fourth connection electrode CNE4 through contact holes penetrating the fourth insulating layer IL4. Accordingly, the driving signal line DSL may transmit the driving signal provided from the first driving circuit DC1 to the gate electrode GE of the first red pixel transistor TR1a of the first red pixel circuit PC1a and the gate electrode GE of the second red pixel transistor TR2a of the second red pixel circuit PC2a.

The bridge line BRL may be configured to electrically connect the first red pixel circuit PC1a disposed in the first-first display area DA1a and the first red light emitting element ED1a disposed in the second-first display area DA2a. The bridge line BRL may include a first end portion electrically connected to the first red pixel circuit PC1a in the first-first display area DA1a and a second end portion electrically connected to the first red light emitting element ED1a in the second-first display area DA2a.

For example, the first end portion of the bridge line BRL may be connected to the third connection electrode CNE3 through a contact hole penetrating the fourth insulating layer IL4. Accordingly, the first end portion of the bridge line BRL may be electrically connected to the source electrode SE of the first red pixel transistor TR1a.

In an embodiment, as illustrated in FIG. 6, the driving signal line DSL and the bridge line BRL may be disposed in a same layer. In an embodiment, the driving signal line DSL and the bridge line BRL may be disposed in different layers.

The sixth connection electrode CNE6 may be connected to the fifth connection electrode CNE5 through a contact hole penetrating the fourth insulating layer IL4.

A fifth insulating layer IL5 may be disposed on the driving signal line DSL, the bridge line BRL, and the sixth connecting electrode CNE6. For example, the fifth insulating layer IL5 may include an organic insulating material.

A seventh connection electrode CNE7, an eighth connection electrode CNE8, and a second shield layer SHL2 may be disposed on the fifth insulating layer IL5. Each of the seventh connection electrode CNE7, the eighth connection electrode CNE8, and the second shield layer SHL2 may include a conductive material. Each of the seventh connection electrode CNE7, the eighth connection electrode CNE8, and the second shield layer SHL2 may have a single layer structure or a multi-layer structure including a plurality of conductive layers.

The seventh connection electrode CNE7 may be connected to the sixth connection electrode CNE6 through a contact hole penetrating the fifth insulating layer IL5.

The eighth connection electrode CNE8 may be connected to the second end portion of the bridge line BRL through a contact hole penetrating the fifth insulating layer IL5.

The second shield layer SHL2 may be disposed on the bridge line BRL. The second shield layer SHL2 may also be disposed on the driving signal line DSL. The second shield layer SHL2 may be disposed between the driving signal line DSL and pixel electrodes PE of the light emitting elements ED. A voltage may be applied to the second shield layer SHL2, and the second shield layer SHL2 may prevent or reduce signal noise and/or signal coupling occurring above the bridge line BRL, above the driving signal line DSL, and/or below the pixel electrodes PE.

The second shield layer SHL2 may define through holes and dummy holes. Each of the through holes and the dummy holes may penetrate the second shield layer SHL2 in the thickness direction. A conductive pattern, which is formed of the same layer as the second shield layer SHL2, may be disposed inside each of the through holes in the second shield layer SHL2. For example, as illustrated in FIG. 6, the seventh connection electrode CNE7 may be disposed inside a fourth through hole TH2a in the second shield layer SHL2, and the eighth connection electrode CNE8 may be disposed inside a fifth through hole TH2b in the second shield layer SHL2, but embodiments are not limited thereto.

Unlike the through holes, a conductive pattern, which is formed of the same layer as the second shield layer SHL2, may not be disposed inside each of the dummy holes in the second shield layer SHL2. For example, as illustrated in FIG. 6, there is no conductive pattern inside a second dummy hole DMH2 in the second shield layer SHL2, and the entire second dummy hole DMH2 may be filled with the sixth insulating layer IL6. Each of the dummy holes may serve as a passage for discharging internal gas generated during forming the insulating layer. That is, each of the dummy holes may be an outgassing passage.

In an embodiment, the seventh connection electrode CNE7, the eighth connection electrode CNE8, and the second shield layer SHL2 may be disposed in a same layer. For example, the seventh connection electrode CNE7, the eighth connection electrode CNE8, and the second shield layer SHL2 may include the same material, and may be substantially simultaneously formed.

A sixth insulating layer IL6 may be disposed on the seventh connection electrode CNE7, the eighth connection electrode CNE8, and the second shield layer SHL2. For example, the sixth insulating layer IL6 may include an organic insulating material.

The first red light emitting element ED1a and the second red light emitting element ED2a may be disposed on the sixth insulating layer IL6. Each of the first red light emitting element ED1a and the second red light emitting element ED2a may include the pixel electrode PE, a first functional layer FL, an emission layer EL, a second functional layer FU, and a common electrode CE.

The pixel electrode PE may be disposed on the sixth insulating layer IL6. The pixel electrode PE may include a conductive material. The pixel electrode PE may have a single layer structure or a multi-layer structure including a plurality of conductive layers. For example, the pixel electrode PE may be the anode.

The pixel electrode PE of the first red light emitting element ED1a disposed in the second-first display area DA2a may be connected to the eighth connection electrode CNE8 through a contact hole penetrating the sixth insulating layer IL6. Accordingly, the pixel electrode PE of the first red light emitting element ED1a disposed in the second-first display area DA2a may be electrically connected to the source electrode SE of the first red pixel transistor TR1a disposed in the first-first display area DA1a through the eighth connection electrode CNE8, the bridge line BRL, and the third connection electrode CNE3.

The pixel electrode PE of the second red light emitting element ED2a disposed in the first-first display area DA1a may be connected to the seventh connection electrode CNE7 through a contact hole penetrating the sixth insulating layer IL6. Accordingly, the pixel electrode PE of the second red light emitting element ED2a disposed in the first-first display area DA1a may be electrically connected to the source electrode SE of the second red pixel transistor TR2a disposed in the first-first display area DA1a through the seventh connection electrode CNE7, the sixth connection electrode CNE6, and the fifth connection electrode CNE5.

The pixel defining layer PDL may be disposed on the pixel electrode PE. The pixel defining layer PDL may cover a peripheral portion of the pixel electrode PE and may define a pixel opening exposing a central portion of the pixel electrode PE. An emission area may be defined by the pixel opening. For example, the pixel defining layer PDL may include an organic insulating material. In an embodiment, the pixel defining layer PDL may further include an inorganic material or an organic material including (or containing) a light blocking material having a black color.

The first functional layer FL may be disposed on the pixel electrode PE. For example, the first functional layer FL may include a hole transport layer and/or a hole injection layer.

In an embodiment, the emission layer EL may be disposed on the first functional layer FL. The emission layer EL may include light emitting material. For example, the emission layer EL may include an organic light emitting material.

In an embodiment, the organic light emitting material may include a low molecular weight organic compound or a high molecular weight organic compound. Examples of the low molecular weight organic compound may include copper phthalocyanine, N,N’-diphenylbenzidine, tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. These materials can be used alone or in a combination thereof.

The second functional layer FU may be disposed on the emission layer EL. For example, the second functional layer FU may include an electron transport layer and/or an electron injection layer.

The common electrode CE may be disposed on the second functional layer FU. In an embodiment, the common electrode CE may be entirely disposed on the display area DA. That is, the common electrode CE of the first red light emitting element ED1a and the common electrode CE of the second red light emitting element ED2a may be integrally connected. For example, the common electrode CE may be the cathode.

As described above, an example of a cross-sectional structure of the display panel DP has been described with reference to FIG. 6, but this is an example and embodiments are not limited thereto, and the number of conductive layers and insulating layers included in the circuit layer CL and the arrangement relationship of the configurations may be variously changed.

According to embodiments, the driving circuits DC may be respectively disposed in the second display areas of the display area DA. Since the light emitting elements ED are also disposed in the second display areas where the driving circuits DC are disposed, a size of an area where an image is not displayed in the display device DD may be reduced. That is, the dead space of the display device DD may be reduced.

In addition, since the driving circuits DC are disposed to be spaced apart from each other in the first direction DR1 in the display area DA, compared to a case where the driving circuits DC are located only on the outer edge of the display area DA, a length and a size of the bridge line BRL may be reduced. Therefore, it is possible to prevent or reduce an increase in signal noise caused by the bridge line BRL becoming excessively long. In addition, since the display panel DP includes the first shield layer SHL1 and the second shield layer SHL2, it is possible to prevent or reduce signal noise and/or signal coupling from occurring in the display area DA. Therefore, a display quality of the display device DD may be improved.

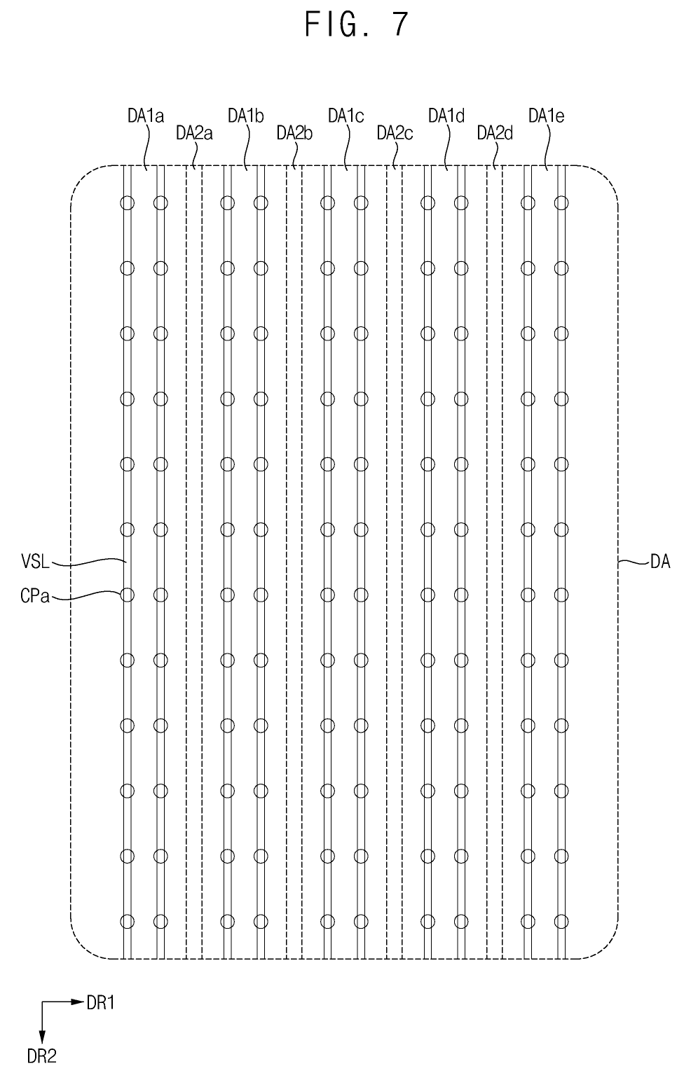

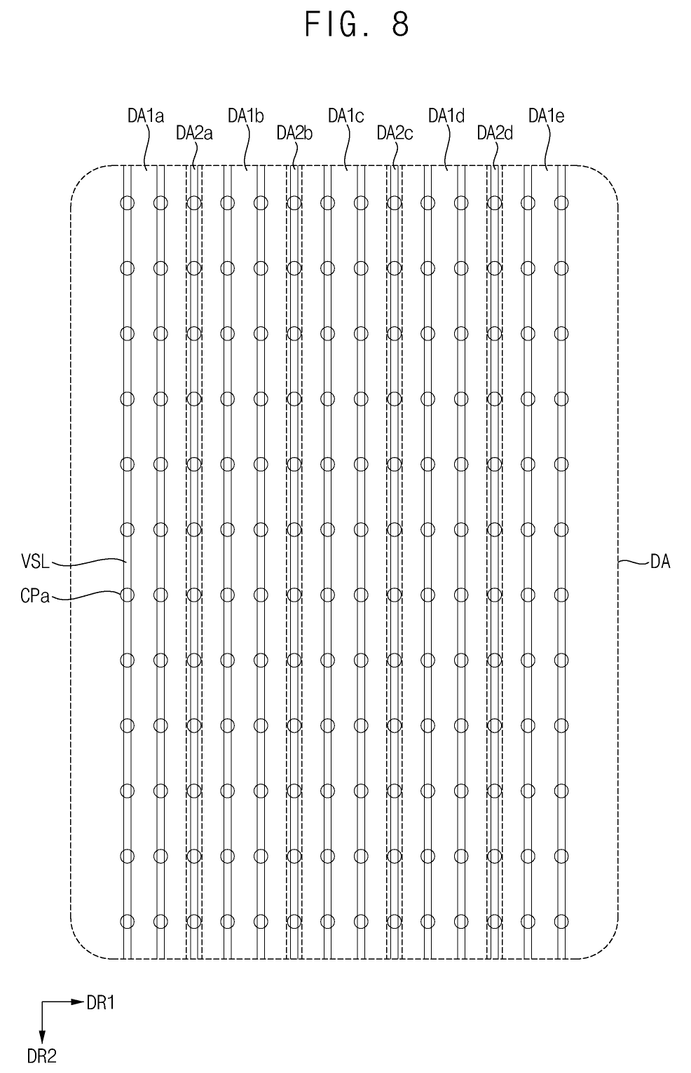

FIG. 7 is a plan view illustrating an example of common voltage lines included in the display device of FIG. 3. FIG. 8 is a plan view illustrating another example of common voltage lines included in the display device of FIG. 3.

Referring to FIGS. 3, 7 and 8, the display panel DP of the display device DD may further include common voltage lines VSL for transmitting the common voltage ELVSS (see FIG. 2) to the light emitting elements ED. In an embodiment, the common voltage lines VSL may be disposed in the display area DA. For example, the common voltage lines VSL may each extend in the second direction DR2, and may be spaced apart from each other in the first direction DR1. Although not illustrated in the drawings, each of the common voltage lines VSL may extend to the second peripheral area PA2, and may receive the common voltage ELVSS through a power pad disposed in the second peripheral area PA2.

In an embodiment, as illustrated in FIG. 7, the common voltage lines VSL may be disposed in the first display areas in which the pixel circuits PC are disposed, and may not be disposed in the second display areas in which the driving circuits DC are disposed. That is, each of the common voltage lines VSL may not overlap the driving circuit DC in a plan view. In other words, each of the common voltage lines VSL may be spaced apart from the driving circuit DC in a plan view. The common voltage lines VSL may be disposed in the first-first display area DA1a, the first-second display area DA1b, the first-third display area DA1c, the first-fourth display area DA1d, and the first-fifth display area DA1e, and may not be disposed in the second-first display area DA2a, the second-second display area DA2b, the second-third display area DA2c, and the second-fourth display area DA2d.

In an embodiment, as illustrated in FIG. 8, the common voltage lines VSL may be disposed in both the first display areas in which the pixel circuits PC are disposed and the second display areas in which the driving circuits DC are disposed. That is, at least one of the common voltage lines VSL may overlap the driving circuit DC in a plan view. The common voltage lines VSL may be disposed in the first-first display area DA1a, the first-second display area DA1b, the first-third display area DA1c, the first-fourth display area DA1d, the first-fifth display area DA1e, the second-first display area DA2a, the second-second display area DA2b, the second-third display area DA2c, and the second-fourth display area DA2d.

Each of the common voltage lines VSL may include connection portions CPa connected to the common electrode CE (see FIG. 6) of the light emitting elements ED. In an embodiment, each of the common voltage lines VSL may include the connection portions CPa spaced apart from each other in the second direction DR2.

According to embodiments, the common voltage line VSL for transmitting the common voltage ELVSS to the common electrode CE may be connected to the common electrode CE in the display area DA. Accordingly, compared to a case where the common voltage line VSL is connected to the common electrode CE in a peripheral area (e.g., the first peripheral area PA1 of FIG. 3), the dead space of the display device DD may be further reduced.

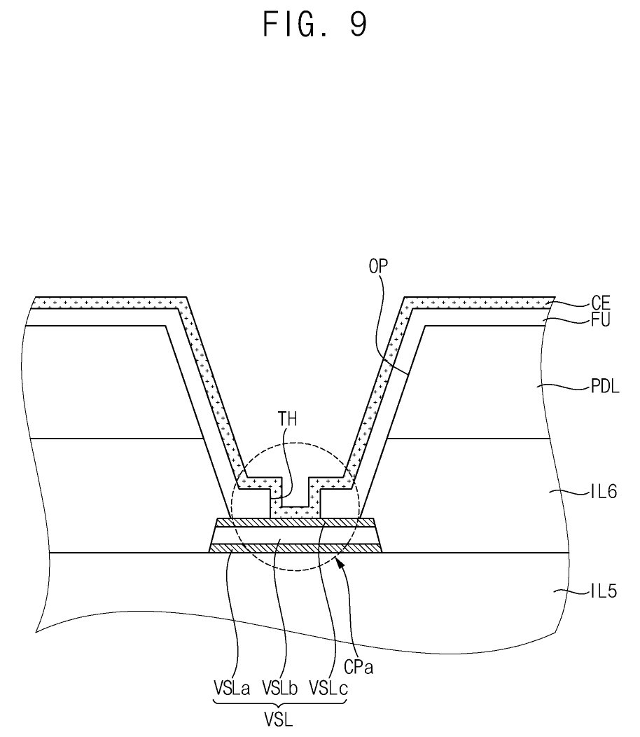

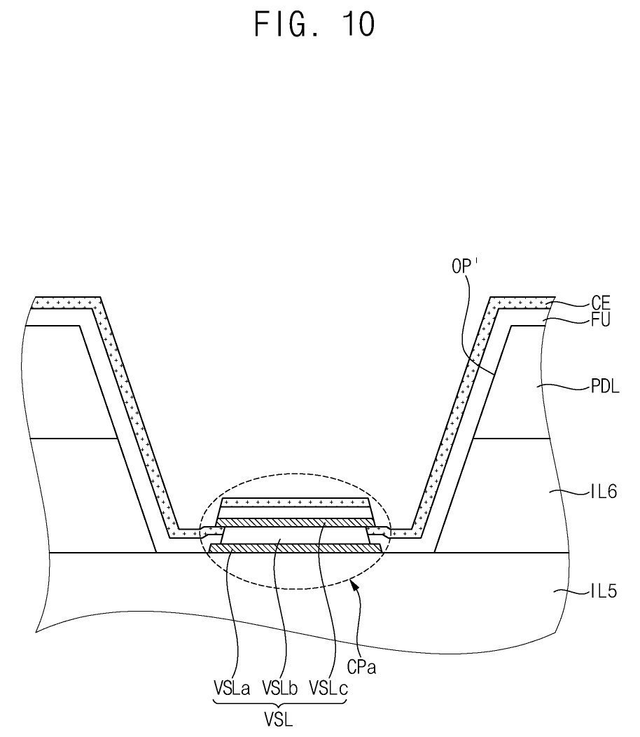

FIG. 9 is a cross-sectional view illustrating an example of a connection portion of a common voltage line included in the display device of FIG. 3. FIG. 10 is a cross-sectional view illustrating another example of a connection portion of a common voltage line included in the display device of FIG. 3.

Hereinafter, examples of a connection structure between the connection portion CPa of the common voltage line VSL and the common electrode CE will be described with reference to FIGS. 9 and 10. FIGS. 9 and 10 illustrate that the common voltage line VSL is disposed in a same layer as the second shield layer SHL2 of FIG. 6 (i.e., disposed between the fifth insulating layer IL5 and the sixth insulating layer IL6), but this is an example and embodiments are not limited thereto, and the common voltage line VSL may be disposed in a same layer as the pixel electrode PE, in a same layer as the bridge line BRL, or in a same layer as the first shield layer SHL1 (see FIG. 6).

Referring to FIG. 9, in an embodiment, the common voltage line VSL may have a multi-layer structure including a first layer VSLa, a second layer VSLb, and a third layer VSLc. For example, each of the first layer VSLa and the third layer VSLc may include Ti, and the second layer VSLb may include Al, but embodiments are not limited thereto.

In an embodiment, an insulating layer (e.g., the sixth insulating layer IL6 and the pixel defining layer PDL) disposed above the common voltage line VSL may define an opening OP’ that exposes at least a portion of an upper surface of the common voltage line VSL (e.g., an upper surface of the third layer VSLc). A portion of the second functional layer FU disposed above the pixel defining layer PDL and the emission layer EL (see FIG. 6) may be located inside the opening OP and may contact the upper surface of the common voltage line VSL.

The second functional layer FU may define a through hole TH that exposes a portion of the upper surface of the common voltage line VSL in the opening OP. For example, after forming the second functional layer FU, the through hole TH may be formed to penetrate the second functional layer FU in the thickness direction in the opening OP, by a laser drilling process.

A portion of the common electrode CE disposed above the second functional layer FU may be located inside the opening OP, and may contact a portion of the upper surface of the common voltage line VSL exposed by the through hole TH in the second functional layer FU. Accordingly, the common electrode CE may be electrically connected to the common voltage line VSL, and the common voltage ELVSS (see FIG. 2) may be transmitted to the common electrode CE.

Referring to FIG. 10, in an embodiment, the common voltage line VSL may have the multi-layer structure including the first layer VSLa, the second layer VSLb, and the third layer VSLc. The common voltage line VSL may include a tip structure. For example, a side surface of each of the first layer VSLa and the third layer VSLc may protrude from a side surface of the second layer VSLb in a direction away from a center of the common voltage line VSL (e.g., in an outward direction). For example, the second layer VSLb may be etched using an etching material that has a higher etching rate for the second layer VSLb than for the first and third layers VSLa and VSLc, thereby forming the common voltage line VSL with the tip structure.

In an embodiment, an insulating layer (e.g., the sixth insulating layer IL6 and the pixel defining layer PDL) disposed above the common voltage line VSL may define an opening OP that exposes the entire upper and side surfaces of the common voltage line VSL.

A portion of the second functional layer FU disposed above the pixel defining layer PDL and the emission layer EL (see FIG. 6) may be located inside the opening OP’. The second functional layer FU may be separated (or disconnected) in the opening OP’ by the tip structure of the common voltage line VSL. As the second functional layer FU is separated (or disconnected) by the tip structure of the common voltage line VSL, the second functional layer FU may expose at least a portion of the side surface of the second layer VSLb. Accordingly, the common electrode CE may contact the side surface of the second layer VSLb in the opening OP’. Accordingly, the common electrode CE may be electrically connected to the common voltage line VSL, and the common voltage ELVSS (see FIG. 2) may be transmitted to the common electrode CE.

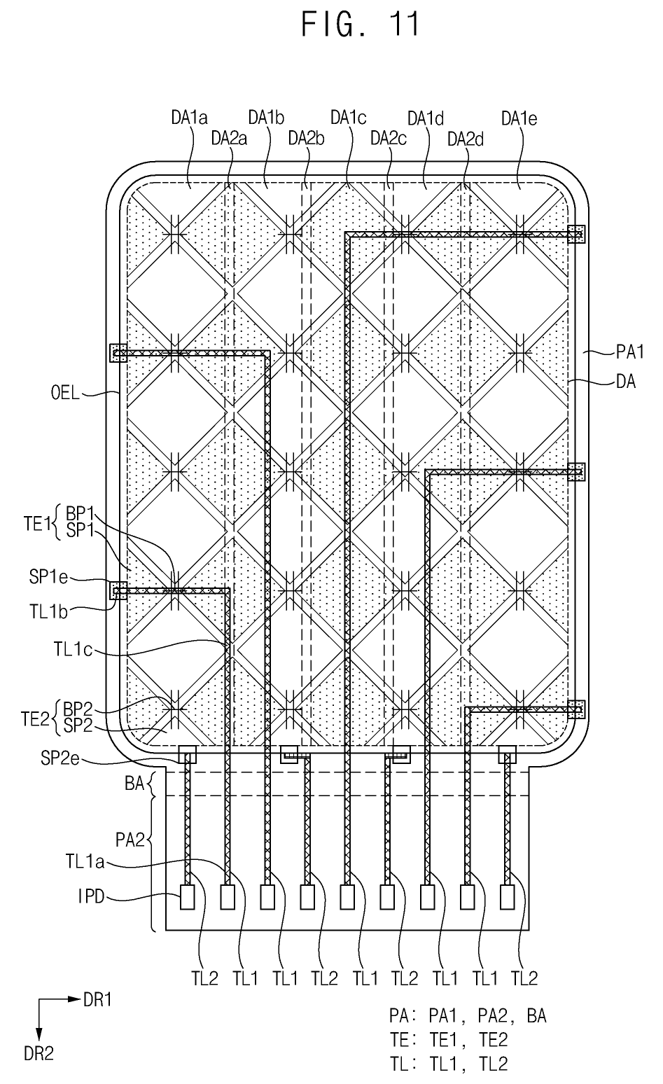

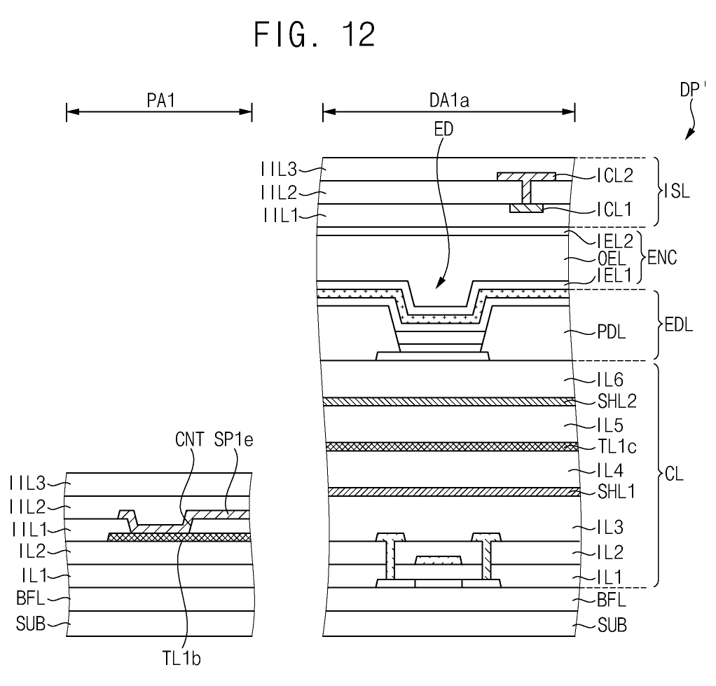

FIG. 11 is a plan view illustrating an example of trace lines included in a display panel according to an embodiment. FIG. 12 is a cross-sectional view illustrating an example of the display panel of FIG. 11.

A display panel DP’ described below with reference to FIGS. 11 and 12 may be substantially the same as or similar to the display panel DP described above with reference to FIGS. 3 and 6, except that the display panel DP’ further includes an encapsulation layer ENC, an input sensing layer ISL, sensing pads IPD, and trace lines TL. Therefore, repeated description will be omitted or simplified.

Referring to FIGS. 11 and 12, the encapsulation layer ENC may be disposed on the light emitting element layer EDL. The encapsulation layer ENC may be disposed on the common electrode CE. The encapsulation layer ENC may seal the light emitting elements ED disposed in the display area DA.

The encapsulation layer ENC may include at least one inorganic encapsulation layer and at least one organic encapsulation layer. For example, the encapsulation layer ENC may include a first inorganic encapsulation layer IEL1 disposed on the common electrode CE, an organic encapsulation layer OEL disposed on the first inorganic encapsulation layer IEL1, and a second inorganic encapsulation layer IEL2 disposed on the organic encapsulation layer OEL.

In an embodiment, the organic encapsulation layer OEL may be entirely disposed on the display area DA, and may extend to a portion of the first peripheral area PA1 adjacent to the display area DA (e.g., an inner portion). The organic encapsulation layer OEL may not be disposed in another portion of the first peripheral area PA1 away from the display area DA (e.g., an outer portion)..

The input sensing layer ISL may be disposed on the encapsulation layer ENC. In an embodiment, the input sensing layer ISL may include a first sensing insulating layer IIL1, a first sensing conductive layer ICL1, a second sensing insulating layer IIL2, a second sensing conductive layer ICL2, and a third sensing insulating layer IIL3. In an embodiment, the first sensing insulating layer IIL1 may be omitted.

Each of the first sensing conductive layer ICL1 and the second sensing conductive layer ICL2 may include a conductive material, such as a metal, an alloy, a transparent conductive material, or the like. Each of the first sensing conductive layer ICL1 and the second sensing conductive layer ICL2 may have a single layer structure or a multi-layer structure including a plurality of conductive layers.

The second sensing insulating layer IIL2 may cover the first sensing conductive layer ICL1, and the third sensing insulating layer IIL3 may cover the second sensing conductive layer ICL2. Each of the first to third sensing insulating layers IIL1, IIL2, and IIL3 may include an inorganic insulating material or an organic insulating material.

As illustrated in FIG. 11, the input sensing layer ISL may include a plurality of sensing electrodes TE. The sensing electrodes TE may include a first sensing electrode TE1 and a second sensing electrode TE2.

The first sensing electrodes TE1 may each extend in the first direction DR1, and may be disposed in the second direction DR2. Each of the first sensing electrodes TE1 may include first sensing patterns SP1 and first conductive patterns BP1. In an embodiment, the first sensing patterns SP1 and the first conductive patterns BP1 may be integrally formed.

The second sensing electrodes TE2 may each extend in the second direction DR2, and may be disposed in the first direction DR1. Each of the second sensing electrodes TE2 may include second sensing patterns SP2 and second conductive patterns BP2. Each of the second conductive patterns BP2 may be a bridge pattern for connecting two second sensing patterns SP2 adjacent to each other in the second direction DR2.

In an embodiment, although not illustrated in FIG. 11 in detail, each of the first sensing electrode TE1 and the second sensing electrode TE2 may include a plurality of conductive lines crossing each other, and may have a mesh shape, in which a plurality of openings are defined, in a plan view. For example, each of the first sensing patterns SP1, the second conductive patterns BP1, and the second sensing patterns SP2 may have a mesh shape in a plan view.

In an embodiment, each of the first sensing patterns SP1, the second sensing patterns SP2, the first conductive patterns BP1, and the second conductive patterns BP2 may be included in the first sensing conductive layer ICL1 and/or the second sensing conductive layer ICL2 of FIG. 12. For example, the first sensing patterns SP1, the second sensing patterns SP2, and the first conductive patterns BP1 may be included in the second sensing conductive layer ICL2, and the second conductive patterns BP2 may be included in the first sensing conductive layer ICL1, but embodiments are not limited thereto.

The sensing pads IPD may be disposed in the peripheral area PA. In an embodiment, the sensing pads IPD may be disposed in the second peripheral area PA2. The sensing pads IPD may receive sensing signals from a sensing driving circuit.

The trace lines TL may connect the sensing electrodes TE and the sensing pads IPD, respectively. The trace lines TL may include first trace lines TL1 and second trace lines TL2.

Each of the first trace lines TL1 may electrically connect a corresponding one of the first sensing electrodes TE1 disposed in the second direction DR2 and a corresponding one of the sensing pads IPD. In an embodiment, a portion of each of the first trace lines TL1 may overlap the display area DA in a plan view.

In an embodiment, as illustrated in FIG. 12, the first trace lines TL1 may be disposed under the light emitting elements ED. The first trace lines TL1 may be included in the circuit layer CL. In an embodiment, the first trace lines TL1 may be disposed between the first shield layer SHL1 and the second shield layer SHL2, but embodiments are not limited thereto.

Each of the first trace lines TL1 may include a first end portion TL1a connected to the corresponding one of the sensing pads IPD, a second end portion TL1b connected to the corresponding one of the first sensing electrodes TE1, and a connection portion TL1c connecting the first end portion TL1a and the second end portion TL1b.

In an embodiment, the first end portion TL1a may be connected to the corresponding one of the sensing pads IPD in the second peripheral area PA2. The second end portion TL1b may be connected to the corresponding one of the first sensing electrodes TE1 in the first peripheral area PA1. The connection portion TL1c between the first end portion TL1a and the second end portion TL1b may extend through the display area DA.

In an embodiment, the second end portion TL1b of the first trace line TL1 may be connected to the corresponding one of the first sensing electrodes TE1 in the outer portion of the first peripheral area PA1 where the organic encapsulation layer OEL is not disposed. That is, the second end portion TL1b of the first trace line TL1 may be connected to the corresponding one of the first sensing electrodes TE1 outside the organic encapsulation layer OEL in a plan view. For example, one of the first sensing patterns SP1 of each of the first sensing electrodes TE1, which is connected to the first trace line TL1, may include an extension portion SP1e that extends to overlap the second end portion TL1b of a corresponding one of the first trace lines TL1. The extension portion SP1e may be connected to the second end portion TL1b of the corresponding one of the first trace lines TL1 through a contact hole CNT penetrating an insulating layer (e.g., the first sensing insulating layer IIL1) disposed under the extension portion SP1e. The contact hole CNT may be located in the outer portion of the first peripheral area PA1 where the organic encapsulation layer OEL is not disposed. That is, the contact hole CNT may not overlap the organic encapsulation layer OEL in a plan view.

Each of the second trace lines TL2 may electrically connect a corresponding one of the second sensing electrodes TE2 disposed in the first direction DR1 and a corresponding one of the sensing pads IPD.

In an embodiment, the second trace lines TL2 may be disposed in a same layer as the first trace lines TL1. That is, the first trace lines TL1 and the second trace lines TL2 may include the same material, and may be substantially simultaneously formed.

In an embodiment, unlike the first trace lines TL1, each of the second trace lines TL2 may not overlap the display area DA in a plan view. For example, a first end portion of each of the second trace lines TL2 may be connected to the corresponding one of the sensing pads IPD in the second peripheral area PA2. A second end portion of each of the second trace lines TL2 may be connected to the corresponding one of the second sensing electrodes TE2 in a portion of the first peripheral area PA1 between the display area DA and the second peripheral area PA2.

In an embodiment, the second end portion of the second trace line TL2 may be connected to the corresponding one of the second sensing electrodes TE2 in the outer portion of the first peripheral area PA1 where the organic encapsulation layer OEL is not disposed. That is, the second end portion of the second trace line TL2 may be connected to the corresponding one of the second sensing electrodes TE2 outside the organic encapsulation layer OEL in a plan view. For example, one of the second sensing patterns SP2 of each of the second sensing electrodes TE2, which is connected to the second trace line TL2, may include an extension portion SP2e that extends to overlap the second end portion of a corresponding one of the second trace lines TL2. The extension portion SP2e may be connected to the second end portion of the corresponding one of the second trace lines TL2 through a contact hole penetrating an insulating layer (e.g., the first sensing insulating layer IIL1) disposed under the extension portion SP2e. The contact hole may be located in the outer portion of the first peripheral area PA1 where the organic encapsulation layer OEL is not disposed (e.g., an area between the organic encapsulation layer OEL and the bending area BA). That is, the contact hole may not overlap the organic encapsulation layer OEL in a plan view.

According to embodiments, the trace lines TL for connecting the sensing pads IPD and the sensing electrodes TE may be included in the circuit layer CL, and thus, at least some of the trace lines TL may be disposed to partially overlap the display area DA. Accordingly, compared to a case where all of the trace lines TL are disposed to overlap only the peripheral area PA outside the display area DA, the dead space of the display device DD may be further reduced.

FIG. 13 is a block diagram illustrating an electronic device according to an embodiment.

Referring to FIG. 13, in an embodiment, an electronic device 900 may include a processor 910, a memory device 920, a storage device 930, an input/output (“I/O”) device 940, a power supply 950, and a display device 960. Here, the display device 960 may correspond to the display device DD described above. The electronic device 900 may further include multiple ports for communicating with a video card, a sound card, a memory card, a universal serial bus (“USB”) device, or the like.

The processor 910 may perform various computing functions or tasks. In an embodiment, the processor 910 may be a microprocessor, a central processing unit (“CPU”), an application processor (“AP”), or the like. The processor 910 may be electrically connected to other components via an address bus, a control bus, a data bus, or the like. In an embodiment, the processor 910 may be electrically connected to an extended bus such as a peripheral component interconnection (“PCI”) bus. The processor 910 may include one or more processors. The one or more processors may be configured to carry out the computing functions or tasks individually or together as group or together in a subset of the whole group of processors.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be electrically connected to other components via the buses or other communication links. In an embodiment, the display device 960 may be included in the I/O device 940.

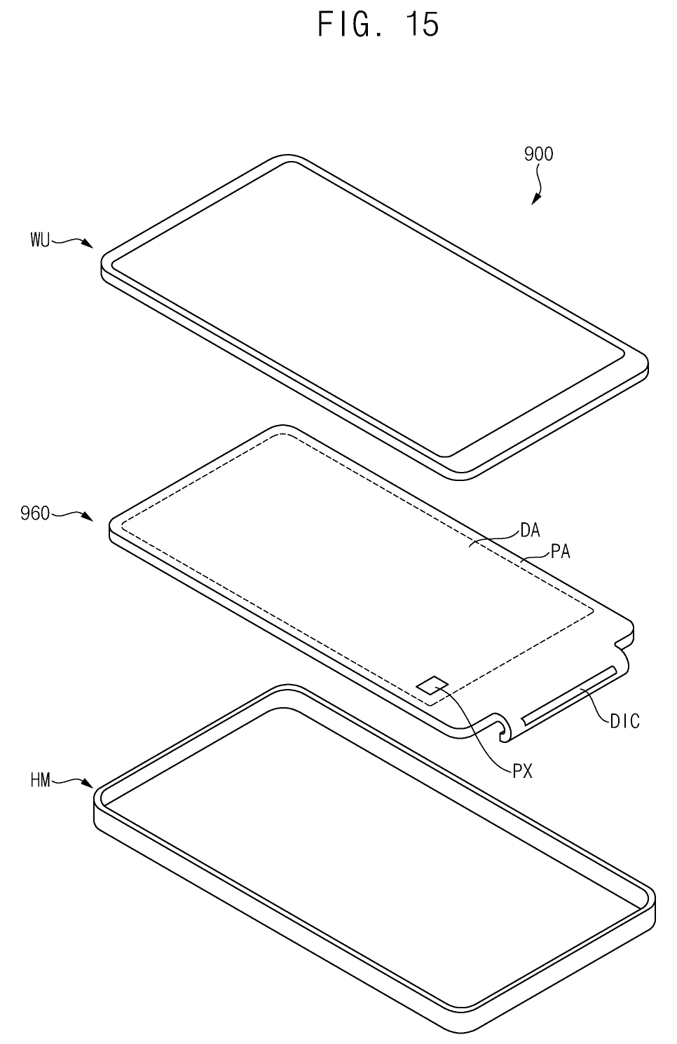

FIG. 14 is a view illustrating an example in which the electronic device of FIG. 13 is implemented as a smartphone. FIG. 15 is an exploded perspective view of the electronic device of FIG. 14.

Referring to FIG. 14, in an embodiment, the electronic device 900 may be implemented as a smartphone. However, the electronic device 900 may not be limited thereto, and for example, the electronic device 900 may be implemented as a television, a mobile phone, a video phone, a smart pad, a smart watch, a tablet PC, a vehicle navigation, a computer monitor, a notebook computer, a head mounted display (“HMD”), a kiosk, or the like. Hereinafter, an embodiment in which the electronic device 900 is implemented as a smartphone will be described in more detail with reference to FIGS. 14 and 15.

Referring to FIGS. 14 and 15, in an embodiment, the electronic device 900 may include a window WU, a display device 960, and a housing HM. The window WU and the housing HM may be combined to define the external appearance of the electronic device 900.

The display device 960 may display an image. The display device 960 may include the display area DA displaying the image and the peripheral area PA located around the display area DA. The pixels PX for generating the image may be disposed in the display area DA. The display device 960 may correspond to the display device DD described above.

The window WU may define a front surface of the electronic device 900. The window WU may have light-transmitting properties. For example, the window WU may include a resin film such as polyimide, ultra-thin glass, or the like.

The housing HM may be combined with the window WU. The housing HM may be combined with the window WU to provide an internal space. The display device 960 may be accommodated in the internal space provided between the housing HM and the window WU. Various components, such as an optical film, a cushion layer, a heating layer, the processor, the memory device, the storage device, the I/O device, the power supply, or the like may be further accommodated in the internal space. The housing HM can include a material having relatively high rigidity. The housing HM can stably protect the components accommodated in the internal space from external impact.

Thus a display panel or electronic device including a display panel may have reduced dead space and improved display quality due to the layout of the display areas and components within the display areas as discussed above.

Although embodiments and implementations have been described herein, other embodiments and modifications will be apparent from this description. Accordingly, the present disclosure is not limited to such embodiments, but rather to the broader scope of the appended claims and various obvious modifications and equivalent arrangements as would be apparent to a person of ordinary skill in the art.

What is claimed is:

1. A display device comprising:
a substrate including a display area and a peripheral area, the display area including a first-first display area, a first-second display area spaced apart from the first-first display area in a first direction, and a second-first display area located between the first-first display area and the first-second display area in the first direction;
pixel circuits disposed in the first-first display area and the first-second display area;
a first driving circuit disposed in the second-first display area, the first driving circuit being configured to provide a first driving signal to the pixel circuits;
light emitting elements disposed in each of the first-first display area, the first-second display area, and the second-first display area;
a first data output pad disposed in the peripheral area, the first data output pad being electrically connected to a first pixel circuit disposed in the first-first display area among the pixel circuits;
a second data output pad disposed in the peripheral area, the second data output pad being electrically connected to a second pixel circuit disposed in the first-second display area among the pixel circuits, the second data output pad being spaced apart from the first data output pad in the first direction; and
a first control output pad disposed in the peripheral area, the first control output pad being electrically connected to the first driving circuit, the first control output pad being located between the first data output pad and the second data output pad in the first direction.

2. The display device of claim 1, wherein the first data output pad, the second data output pad, and the first control output pad are disposed in a row in the first direction.

3. The display device of claim 1, further comprising:
a first data line disposed in the first-first display area, the first data line being electrically connected to the first data output pad;
a second data line disposed in the first-second display area, the second data line being electrically connected to the second data output pad;
a first data connection line connecting the first data output pad and the first data line;
a second data connection line connecting the second data output pad and the second data line, the second data connection line being spaced apart from the first data connection line in the first direction; and
a first control connection line connecting the first control output pad and the first driving circuit, the first control connection line being located between the first data connection line and the second data connection line in the first direction.

4. The display device of claim 3, further comprising:
a first crack detection circuit disposed between the first data output pad and the first-first display area in a second direction crossing the first direction; and
a second crack detection circuit disposed between the second data output pad and the first-second display area in the second direction, the second crack detection circuit being spaced apart from the first crack detection circuit in the first direction,
wherein the first control connection line is located between the first crack detection circuit and the second crack detection circuit in the first direction.

5. The display device of claim 1, wherein the display area further includes a first-third display area spaced apart from the first-second display area in the first direction and a second-second display area located between the first-second display area and the first-third display area in the first direction,
wherein the pixel circuits are further disposed in the first-third display area, and
wherein the light emitting elements are further disposed in the first-third display area and the second-second display area.

6. The display device of claim 5, further comprising:
a second driving circuit disposed in the second-second display area, the second driving circuit being configured to provide a second driving signal to the pixel circuits;
a third data output pad disposed in the peripheral area, the third data output pad being electrically connected to a third pixel circuit disposed in the first-third display area among the pixel circuits, the third data output pad being spaced apart from the second data output pad in the first direction; and
a second control output pad disposed in the peripheral area, the second control output pad being electrically connected to the second driving circuit, the second control output pad being located between the second data output pad and the third data output pad in the first direction.

7. The display device of claim 6, wherein each of the first driving circuit and the second driving circuit is either a scan driving circuit or an emission driving circuit.

8. The display device of claim 1, wherein the pixel circuits further include a third pixel circuit disposed in the first-first display area, and
wherein the light emitting elements include a first light emitting element disposed in the second-first display area and electrically connected to the first pixel circuit, and a second light emitting element disposed in the first-first display area and electrically connected to the third pixel circuit.

9. The display device of claim 8, wherein the first pixel circuit is located between the second-first display area and the third pixel circuit in the first direction.

10. The display device of claim 8, further comprising:
a bridge line including a first end portion electrically connected to the first pixel circuit in the first-first display area and a second end portion electrically connected to the first light emitting element in the second-first display area; and
a first shield layer disposed between the bridge line and the first driving circuit.

11. The display device of claim 10, wherein the first shield layer defines a first through hole and a first dummy hole,
wherein a conductive pattern, which is in a same layer as the first shield layer, is disposed inside the first through hole, and
wherein there is no conductive pattern inside the first dummy hole.

12. The display device of claim 10, further comprising:
a driving signal line disposed on the first shield layer, the driving signal line being configured to transmit the first driving signal provided from the first driving circuit to the first pixel circuit and the third pixel circuit.

13. The display device of claim 12, wherein the driving signal line is in a same layer as the bridge line.

14. The display device of claim 10, further comprising:
a second shield layer disposed on the bridge line.

15. The display device of claim 1, further comprising:
a common voltage line disposed in the display area and to which a common voltage is applied,
wherein the common voltage line is connected to a common electrode of the light emitting elements in the display area.

16. The display device of claim 1, further comprising:
an organic encapsulating layer disposed on the light emitting elements;
an input sensing layer disposed on the organic encapsulating layer, the input sensing layer including a first sensing electrode and a second sensing electrode; and
a first trace line disposed under the light emitting elements, the first trace line electrically connecting the first sensing electrode and a first sensing pad.

17. The display device of claim 16, wherein the first trace line includes:
a first end portion connected to the first sensing pad in the peripheral area;
a second end portion connected to the first sensing electrode in the peripheral area; and
a connection portion connecting the first end portion and the second end portion, the connection portion extending through the display area.

18. The display device of claim 17, wherein the second end portion of the first trace line is connected to the first sensing electrode outside the organic encapsulating layer in a plan view.

19. The display device of claim 16, further comprising:
a second trace line in a same layer as the first trace line, the second trace line electrically connecting the second sensing electrode and a second sensing pad.

20. An electronic device comprising:
a display device displaying an image; and
a housing accommodating the display device,
wherein the display device includes:
a substrate including a display area and a peripheral area, the display area including a first-first display area, a first-second display area spaced apart from the first-first display area in a first direction, and a second-first display area located between the first-first display area and the first-second display area in the first direction;
pixel circuits disposed in the first-first display area and the first-second display area;
a first driving circuit disposed in the second-first display area, the first driving circuit being configured to provide a first driving signal to the pixel circuits;
light emitting elements disposed in each of the first-first display area, the first-second display area, and the second-first display area;
a first data output pad disposed in the peripheral area, the first data output pad being electrically connected to a first pixel circuit disposed in the first-first display area among the pixel circuits;
a second data output pad disposed in the peripheral area, the second data output pad being electrically connected to a second pixel circuit disposed in the first-second display area among the pixel circuits, the second data output pad being spaced apart from the first data output pad in the first direction; and
a first control output pad disposed in the peripheral area, the first control output pad being electrically connected to the first driving circuit, the first control output pad being located between the first data output pad and the second data output pad in the first direction.
